(19) United States
(12) Patent Application Publication
(10) Pub. No.: US 2026/0080955 A1
(43) Pub. Date: Mar. 19, 2026

(54) MEMORY SYSTEM AND MEMORY DEVICE

(71) Applicant: Kioxia Corporation, Tokyo (JP)

(72) Inventor: Yasuhiko KUROSAWA, Fujisawa (JP)

(73) Assignee: Kioxia Corporation, Tokyo (JP)

(21) Appl. No.: 19/075,921

(22) Filed: Mar. 11, 2025

(30) Foreign Application Priority Data
Sep. 19, 2024 (JP) 2024-162534

(51) Int. Cl. G11C 16/34; G11C 16/08; G11C 16/26

(52) U.S. Cl. CPC G11C 16/3404; G11C 16/08; G11C 16/26

(57) ABSTRACT

According to one embodiment, a memory system includes: a memory device including memory cells for storing data; and a memory controller configured to control an operation of the memory device, wherein the memory device is configured to: acquire, in response to a first read command set, a first determination result of threshold voltages of the memory cells based on a first read level related to a first threshold voltage distribution and a second determination result of threshold voltages of the memory cells based on a first lower-voltage side offset read level, the first lower-voltage side offset read level is obtained by offsetting the first read level to a lower-voltage side, acquire a first number of mismatches between the first determination result and the second determination result, and calculate a first correction amount of the first read level based on the first number of mismatches.

### CROSS-REFERENCE TO RELATED APPLICATIONS

This application is based upon and claims the benefit of priority from Japanese Patent Application No. 2024-162534, filed Sep. 19, 2024, the entire contents of which are incorporated herein by reference.

### FIELD

Embodiments described herein relate generally to memory systems and memory devices.

### BACKGROUND

As a memory system, a solid state drive (SSD) including a memory controller and a memory device is known. The memory device is, for example, a non-volatile memory. The nonvolatile memory is, for example, a NAND flash memory.

### BRIEF DESCRIPTION OF THE DRAWINGS

FIG. 1 is a block diagram illustrating a configuration example of a memory system of a first embodiment.

FIG. 2 is a block diagram illustrating a configuration example of the memory system of the first embodiment.

FIG. 3 is a circuit diagram illustrating a configuration example of a memory cell array of a memory device.

FIG. 4 is a schematic diagram for illustrating a relationship between a threshold voltage of a memory cell and data.

FIG. 5 is a diagram for illustrating a command sequence of the memory system of the first embodiment.

FIG. 6 is a schematic diagram for illustrating an overview of a read operation of the memory system of the first embodiment.

FIG. 7 is a flowchart illustrating a read operation of the memory system of the first embodiment.

FIG. 8 is a schematic diagram for illustrating a read operation of the memory system of the first embodiment.

FIG. 9 is a schematic diagram for illustrating a read operation of the memory system of the first embodiment.

FIG. 10 is a schematic diagram for illustrating a read operation of the memory system of the first embodiment.

FIG. 11 is a schematic diagram for illustrating a read operation of the memory system of the first embodiment.

FIG. 12 is a schematic diagram for illustrating a read operation of the memory system of the first embodiment.

FIG. 13 is a schematic diagram for illustrating a read operation of the memory system of the first embodiment.

FIG. 14 is a schematic diagram for illustrating a read operation of the memory system of the first embodiment.

FIG. 15 is a schematic diagram for illustrating a read operation of the memory system of the first embodiment.

FIG. 16 is a schematic diagram for illustrating a read operation of the memory system of the first embodiment.

FIG. 17 is a schematic diagram for illustrating a read operation of the memory system of the first embodiment.

FIG. 18 is a schematic diagram for illustrating a read operation of the memory system of the first embodiment.

FIG. 19 is a schematic diagram for illustrating a read operation of the memory system of the first embodiment.

FIG. 20 is a schematic diagram for illustrating a read operation of the memory system of the first embodiment.

FIG. 21 is a schematic diagram for illustrating a memory system of a second embodiment.

FIG. 22 is a schematic diagram for illustrating a memory system of a fifth embodiment.

FIG. 23 is a schematic diagram for illustrating a memory system of a seventh embodiment.

FIG. 24 is a schematic diagram for illustrating a memory system of a tenth embodiment.

FIG. 25 is a schematic diagram for illustrating a memory system of an eleventh embodiment.

### DETAILED DESCRIPTION

In general, according to one embodiment, a memory system includes: a memory device including a plurality of memory cells for storing data; and a memory controller configured to control an operation of the memory device, wherein the memory device is configured to: acquire, in response to a first read command set, a first determination result of threshold voltages of the memory cells based on a first read level related to a first threshold voltage distribution and a second determination result of threshold voltages of the memory cells based on a first lower-voltage side offset read level, the first lower-voltage side offset read level is obtained by offsetting the first read level to a lower-voltage side, acquire a first number of mismatches between the first determination result and the second determination result, and calculate a first correction amount of the first read level based on the first number of mismatches.

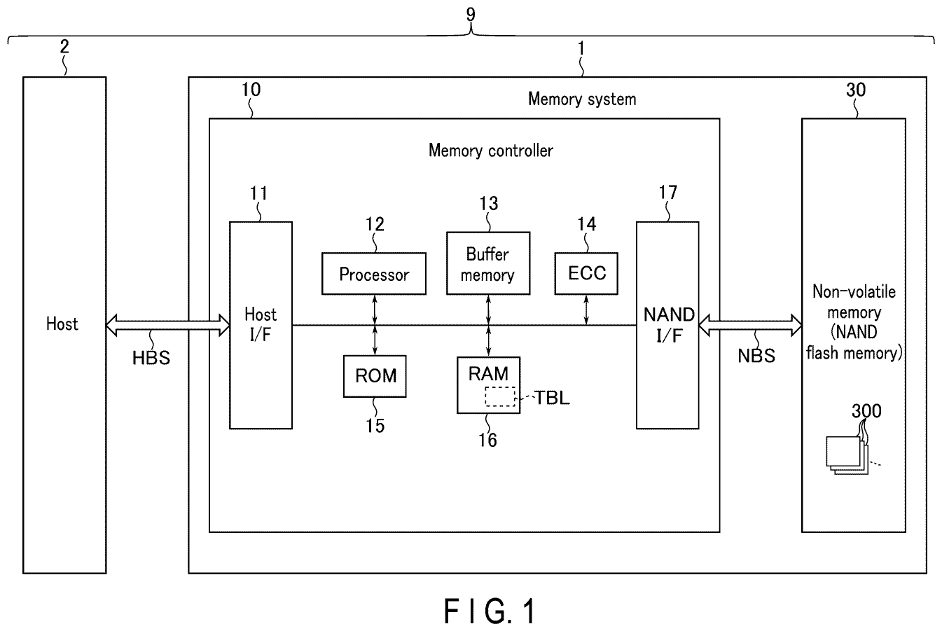

A memory system and a memory device of embodiments will be described with reference to FIGS. 1 to 25. In the following description, elements having the same function and configuration are denoted by the same reference numerals. In addition, in each of the following embodiments, in a case where the components (for example, circuits, wirings, various voltages and signals, and the like) denoted by reference numerals with numeric characters/alphabetic characters for distinguishing at the end do not need to be distinguished from each other, a description (reference numeral) in which the numeric characters/alphabetic characters at the end are omitted is used.

### EMBODIMENTS

### (1) First Embodiment

A memory system, a memory device, and a method for controlling the memory system of a first embodiment will be described with reference to FIGS. 1 to 20.

### (a) Configuration Example

A configuration example of a memory system of the present embodiment will be described with reference to FIGS. 1 to 6.

(a-1) Overall Configuration

FIG. 1 is a block diagram illustrating a configuration example of an information processing system 9.

As illustrated in FIG. 1, the information processing system 9 includes a memory system 1 and a host 2 of the present embodiment.

The memory system 1 is a device that stores data. The memory system 1 is, for example, a solid state drive (SSD), a universal flash storage (UFS) device, a universal serial bus (USB) memory, a multi-media card (MMC), or an SD™ card. The memory system 1 can be connected to the host 2 via a host bus HBS. The memory system 1 performs processing based on a request (command or host command) received from the host 2 or a spontaneous processing request generated in the memory system 1.

The host 2 is a computing device that controls the memory system 1. The host 2 is, for example, a personal computer, a server, a mobile device, an in-vehicle device, or a digital camera.

(a-1-1) Internal Configuration of Memory System

The memory system 1 includes a memory controller 10 and a memory device 30. The memory device 30 is, for example, a non-volatile memory. More specifically, the memory device 30 is a non-volatile semiconductor memory such as a NAND flash memory. Hereinafter, the memory device 30 is referred to as a non-volatile memory 30 or a NAND memory 30.

The memory controller 10 is a device that controls the NAND memory 30. The memory controller 10 is connected to the host 2 via the host bus HBS. The memory controller 10 receives a request from the host 2 via the host bus HBS. The type of the host bus HBS depends on an application applied to the memory system 1. In a case where the memory system 1 is an SSD, the host bus HBS conforms to, for example, the serial attached SCSI (SAS), the serial ATA (SATA), or the peripheral component interconnect express (PCIe™) standards. In a case where the memory system 1 is a UFS device, the host bus HBS conforms to the M-PHY standard. In a case where the memory system 1 is a USB memory, the host bus HBS conforms to the USB standard. In a case where the memory system 1 is an SD™ card, the host bus HBS conforms to the SD™ standard.

The memory controller 10 controls the NAND memory 30 via a NAND bus NBS based on a request received from the host 2 or a spontaneous processing request generated in the memory system 1. The NAND bus NBS conforms to, for example, the Toggle NAND Flash Interface standard or the Open NAND Flash Interface standard.

The NAND memory 30 is a device that stores data. The NAND memory 30 includes a plurality of memory cells. Each of the plurality of memory cells stores data in a non-volatile manner according to a threshold voltage of the memory cell. The NAND memory 30 stores the data received from the memory controller 10 in the plurality of memory cells in a non-volatile manner. The NAND memory 30 outputs data read from the plurality of memory cells to the memory controller 10.

(a-1-2) Memory Controller

An example of an internal configuration of the memory controller 10 will be described.

As illustrated in FIG. 1, the memory controller 10 includes a host interface (host I/F) circuit 11, a processor 12, a buffer memory 13, an error checking and correcting (ECC) circuit 14, a read only memory (ROM) 15, a random access memory (RAM) 16, and a NAND interface (NAND I/F) circuit 17. The memory controller 10 can be configured as, for example, a system-on-a-chip (SoC). The memory controller 10 may include a plurality of chips. The function of each unit of the memory controller 10 can be implemented by a dedicated hardware circuit, a processor that executes a program (firmware), or a combination thereof.

The host interface circuit 11 is a circuit that manages communication between the memory controller 10 and the host 2. The host interface circuit 11 is connected to the host 2 via the host bus HBS.

The processor 12 is a control circuit of the memory controller 10. The processor 12 is, for example, a central processing unit (CPU). The processor 12 controls the operation of the entire memory controller 10 by executing a program (firmware) stored in the ROM 15. For example, upon receiving a write request from the host 2, the processor 12 controls the write operation based on the received write request. For example, upon receiving a read request from the host 2, the processor 12 controls the read operation based on the received read request.

The buffer memory 13 is a memory that temporarily stores data. The buffer memory 13 is, for example, a static random access memory (SRAM). The buffer memory 13 temporarily stores write data, read data, and the like. The write data is data to be written to the NAND memory 30. The read data is data read from the NAND memory 30.

The ECC circuit 14 is a circuit that performs ECC processing for data error correction. The ECC circuit 14 generates an error correction code based on the write data in predetermined units during the data write operation. The ECC circuit 14 generates a syndrome based on an error correction code in predetermined units and detects an error, during the data read operation. The ECC circuit 14 corrects the detected error.

The ROM 15 is a non-volatile memory. The ROM 15 is, for example, an electrically erasable programmable read-only memory (EEPROM™). The ROM 15 stores programs such as firmware.

The RAM 16 is a volatile memory. The RAM 16 is, for example, an SRAM or a dynamic random access memory (DRAM). The RAM 16 is used as a work area of the processor 12. The RAM 16 stores firmware for managing the NAND memory 30 and various types of management information. The RAM 16 stores, for example, various tables TBL.

The NAND interface circuit 17 is a circuit that manages communication between the memory controller 10 and the NAND memory 30. The NAND interface circuit 17 is connected to the NAND memory 30 via the NAND bus NBS. For example, the NAND interface circuit 17 controls the transfer of data, commands, addresses, and the like between the memory controller 10 and the NAND memory 30.

For example, the NAND memory 30 includes a plurality of memory chips (memory dies) 300.

(a-1-3) NAND Flash Memory

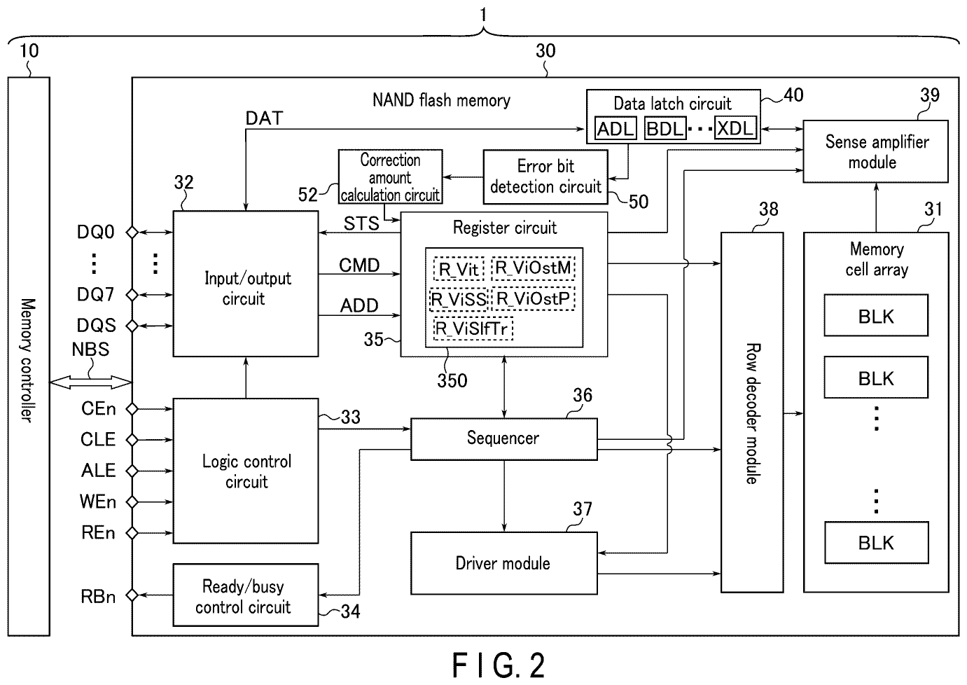

A configuration of the NAND memory 30 will be described with reference to FIG. 2.

FIG. 2 is a block diagram illustrating an example of a configuration of the NAND memory 30. The NAND memory 30 includes a memory cell array 31, an input/output circuit 32, a logic control circuit 33, a ready/busy control circuit 34, a register circuit 35, a sequencer 36, a driver module 37, a row decoder module 38, a sense amplifier module 39, a data latch circuit 40, an error bit detection circuit 50, and a correction amount calculation circuit 52.

The memory cell array 31 is a circuit that stores data. The memory cell array 31 includes one or more blocks BLK. The block BLK is, for example, a set of a plurality of memory cells from which data is collectively erased.

A plurality of bit lines and a plurality of word lines are provided in the memory cell array 31. Each memory cell is associated with, for example, one bit line and one word line. Details of the memory cell array 31 will be described below.

The input/output circuit 32 is a circuit that transmits and receives signals and information to and from the memory controller 10. The input/output circuit 32 transmits and receives an input/output signal DQ (for example, 8-bit signal DQ0, . . . , and DQ7) and a data strobe signal DQS to and from the memory controller 10. The signal DQ is an entity of data transmitted and received between the NAND memory 30 and the memory controller 10. The signal DQ is, for example, a command CMD, an address ADD, status information STS, and data DAT.

The command CMD includes, for example, a command for causing the sequencer 36 to execute a read operation, a write operation, or an erase operation.

The address ADD includes, for example, a row address and a column address. The row address includes a block address and a page address (word line address). The block address, the page address, and the column address are used to select, for example, the block BLK, the word line, and the bit line, respectively.

The status information STS is used to notify the memory controller 10 whether the operation has been normally ended.

The data DAT is write data or read data.

In the input/output circuit 32, the unit of input/output (hereinafter referred to as I/O unit) of the signal DQ is 8 bits.

The signal DQS is a signal (clock signal) for controlling transmission and reception timings of the signal DQ. For example, during writing data, the signal DQS is transmitted from the memory controller 10 to the NAND memory 30 together with the signal DQ including the write data. The input/output circuit 32 receives a signal DQ including write data in synchronization with the signal DQS. During reading data, the signal DQS is transmitted from the input/output circuit 32 to the memory controller 10 together with the signal DQ including the read data. The memory controller 10 receives the signal DQ including the read data in synchronization with the signal DQS. It should be noted that the input/output circuit 32 may receive the signal DQS from the memory controller 10 via the logic control circuit 33.

The input/output circuit 32 transmits the command CMD in the signal DQ to the register circuit 35. The input/output circuit 32 transmits the address ADD in the signal DQ to the register circuit 35. The input/output circuit 32 receives the status information STS from the register circuit 35. The input/output circuit 32 transmits and receives the data DAT in the signal DQ to and from the data latch circuit 40.

The logic control circuit 33 is a circuit that controls the input/output circuit 32 and the sequencer 36 based on a control signal. The logic control circuit 33 receives control signals such as a chip enable signal CEn, a command latch enable signal CLE, an address latch enable signal ALE, a write enable signal WEn, and a read enable signal REn from the memory controller 10. The signal CEn is a signal for enabling the chip 300 of the NAND memory 30. The signal CLE is a signal indicating that the signal DQ received by the NAND memory 30 is the command CMD. The signal ALE is a signal indicating that the signal DQ received by the NAND memory 30 is the address ADD. The signal WEn is a signal that commands the NAND memory 30 to input the signal DQ. The signal REn is a signal that commands the NAND memory 30 to output the signal DQ. The NAND memory 30 generates a signal DQS based on the signal REn. The NAND memory 30 outputs a signal DQ to the memory controller 10 based on the generated signal DQS.

The ready/busy control circuit 34 is a circuit that notifies the memory controller 10 of the operating situation of the sequencer 36. The ready/busy control circuit 34 transmits a ready/busy signal RBn to the memory controller 10 based on the operating situation of the sequencer 36. The signal RBn is a signal indicating which of a ready state or a busy state the NAND memory 30 is in. The signal level of the signal RBn is a high level (“H” level) when, for example, the NAND memory 30 is in the ready state. The ready state is a state in which the NAND memory 30 can receive the command CMD from the memory controller 10. The signal level of the signal RBn is a low level (“L” level) when, for example, the NAND memory 30 is in the busy state. The busy state is a state in which the NAND memory 30 cannot receive the command CMD from the memory controller 10.

The register circuit 35 is a circuit that temporarily stores information. The register circuit 35 temporarily stores, for example, the command CMD, the address ADD, the status information STS, and the setting information of the NAND memory 30.

The setting information includes, for example, information related to setting values of various voltages used for the NAND memory 30. The setting information is stored in, for example, the setting information register 350.

For example, the setting information register 350 includes a register (R_Vit) for a static shift value of a read level during a manufacturing test of the NAND memory 30. The static shift value is a value, which is set at the time of shipment of the memory system, for adjusting the read level according to variations in products. The number (i) of registers for a static shift value is provided corresponding to the number of read levels used according to the mode of the number of bits stored in the memory cell. The mode of the number of bits stored by the memory cell will be described below in detail. For example, in a case where the mode of the NAND memory 30 is a mode for storing 3-bit data in the memory cell MC, “i” is any one of values of 0 or more and 7 or less.

The setting information register 350 includes a register for a designated shift value (R_ViSS) that stores a designated shift value of a read level to be designated from the memory controller 10. The designated shift value is a value that indicates the movement amount of the read level managed in the table TBL in the memory controller 10. The NAND memory 30 receives the designated shift value from the memory controller 10 and stores the designated shift value in the register for a designated shift value. The number (i) of registers for a designated shift value corresponds to the number of read levels to be described below.

The setting information register 350 includes a register for a dynamic shift value (R_ViSlfTr) that stores a dynamic shift value of the read level. The dynamic shift value is a value for adjusting the read level. The dynamic shift value is obtained by an automatic adjustment read operation described below. The number (i) of registers for a dynamic shift value corresponds to the number of read levels to be described below.

The setting information register 350 includes a register for a minus offset value (R_ViOstM). The register for a minus offset value stores an offset voltage value for setting a voltage value lower than a voltage value of a certain normal read level. The number (i) of registers for a minus offset value corresponds to the number of read levels to be described below.

The setting information register 350 includes a register for a plus offset value (R_ViOstP). The register for a plus offset value stores an offset voltage value for setting a voltage value higher than a voltage value of a certain normal read level. The number (i) of registers for a plus offset value corresponds to the number of read levels to be described below.

It should be noted that the setting information register 350 may include a register (R_Vi_0) that stores a reference voltage value (default value Vi_0) of each read level.

The sequencer 36 is a circuit that controls the operation of other circuits according to a predetermined program. The sequencer 36 controls the operation of the entire NAND memory 30. For example, the sequencer 36 controls the ready/busy control circuit 4, the driver module 37, the row decoder module 38, and the sense amplifier module 39 based on the command CMD stored in the register circuit 35. For example, the sequencer 36 executes a read operation, a write operation, and an erase operation.

The driver module 37 is a circuit that generates various voltages used in the read operation, the write operation, and the erase operation. The driver module 37 applies the generated voltage to the signal line corresponding to the selected word line based on the page address stored in the register circuit 35. The driver module 37 includes a plurality of charge pumps for generating a plurality of respective voltages.

The row decoder module 38 is a circuit that selects one block BLK in the memory cell array 31 based on the block address stored in the register circuit 35. The row decoder module 38 transfers the voltage applied to the signal line corresponding to the selected word line to the selected word line in the selected block BLK.

In the write operation, the sense amplifier module 39 receives write data DAT from the input/output circuit 32 via the data latch circuit 40. The sense amplifier module 39 applies a voltage based on the received write data DAT to the bit line. In the read operation, the sense amplifier module 39 determines the data stored in the memory cell based on whether or not a current has flowed through the bit line or the voltage of the bit line. The sense amplifier module 39 transfers the determination result as read data DAT to the input/output circuit 32 via the data latch circuit 40.

The data latch circuit 40 temporarily stores write data or read data. For example, in the write operation, the data latch circuit 40 temporarily stores the write data received from the input/output circuit 32 and transmits the write data to the sense amplifier module 39. In the read operation, the data latch circuit 40 temporarily stores the data from the sense amplifier module 39 and transmits the data to the input/output circuit 32.

The data latch circuit 40 includes a plurality of data latches ADL, BDL, . . . , and XDL. Hereinafter, in a case where the plurality of data latches ADL, BDL, . . . , and XDL are not distinguished, each of the data latches ADL, BDL, . . . , and XDL of the data latch circuit 40 is also denoted as a data latch DL. Each data latch DL temporarily stores data of a certain data size in the write data and the read data. For example, each data latch DL can store data of about 18 kByte including data for one page (data of 16 kByte) in the NAND memory 30 and redundant data (data of about 2 kByte). The redundant data includes ECC parity and data used by the memory controller 10 and the like. Input and output of data of the data latch DL may be controlled by, for example, the sequencer 36 or an error bit detection circuit 50 to be described below. The data of the data latch DL may be transferred from a certain data latch DL to another data latch DL under the control of the sequencer 36 or the error bit detection circuit 50.

The error bit detection circuit 50 is a circuit that detects an error bit of data read from the memory cell array 31. The error bit detection circuit 50 detects an error bit included in the data by various kinds of calculation processing (for example, exclusive OR operation) using the data in the data latch DL. The error bit detection circuit 50 can count the number of error bits included in the data of a certain unit (data length). It should be noted that the calculation processing using the data of the data latch DL may be executed by the sequencer 36.

The correction amount calculation circuit 52 is a circuit that calculates a dynamic shift value of the read voltage (read level). The correction amount calculation circuit 52 calculates a dynamic shift value for setting the voltage value of the read level to a more suitable value based on the detection result of the error bit by the error bit detection circuit 50. The read level is corrected by the calculated dynamic shift value. The correction amount calculation circuit 52 transmits the calculated dynamic shift value to the register circuit 35. For example, the calculated dynamic shift value is stored in the register for a dynamic shift value (R_ViSlfTr) of the setting information register 350. The correction amount calculation circuit 52 may include a register that stores setting values of various voltages used for the read operation.

It should be noted that the error bit detection circuit 50 and the correction amount calculation circuit 52 may be provided in the sequencer 36 as a functional block or an internal circuit of the sequencer 36.

(a-1-3-1) Circuit Example of Memory Cell Array

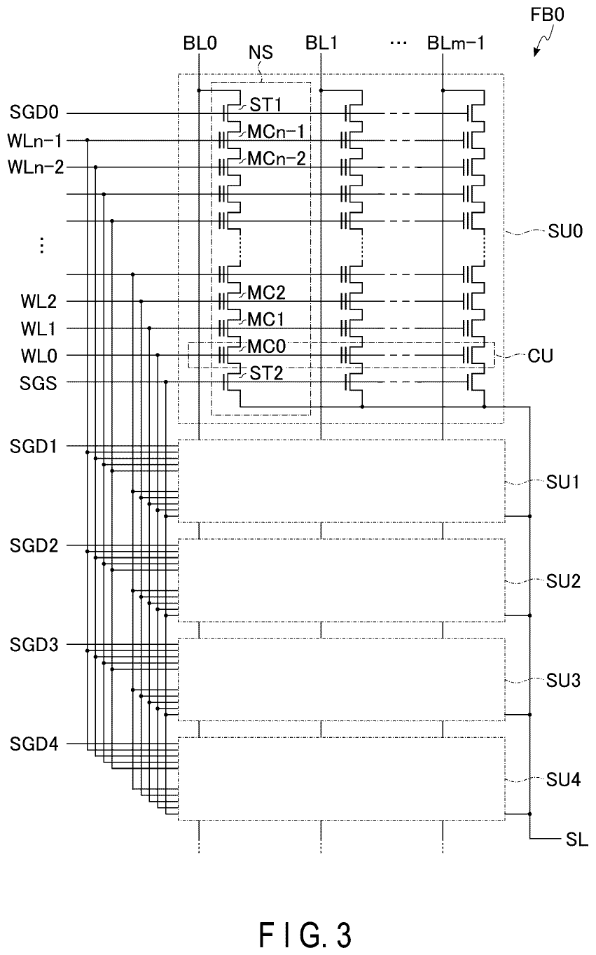

A circuit configuration of the memory cell array 31 will be described with reference to FIG. 3. FIG. 3 is a circuit diagram of the memory cell array 31. FIG. 3 illustrates a circuit configuration of the block BLK included in the memory cell array 31 as an example of a circuit configuration of the memory cell array 31.

The block BLK includes, for example, five string units SU0, SU1, SU2, SU3, and SU4. Each string unit SU is, for example, a set of a plurality of NAND strings NS collectively selected in the write operation or the read operation. Each string unit SU includes a plurality of NAND strings NS associated with respective bit lines BL0, BL1, . . . , and BLm−1, where m is an integer of 1 or more. The NAND string NS is a set of a plurality of memory cells MC (MC0, . . . , and MCn−1) connected in series. Each NAND string NS includes, for example, memory cells MC0, MC1, MC2, MC3, . . . , MCn−2, and MCn−1, a select transistor ST1, and a select transistor ST2, where n is an integer of 1 or more. The memory cell (also referred to as a memory cell transistor) MC is a field effect transistor including a control gate and a charge storage layer. The select transistors ST1 and ST2 are switching elements. Each of the select transistors ST1 and ST2 is used to select the string unit SU during various operations.

In each NAND string NS, the memory cells MC0, . . . , and MCn−1 are connected in series. The drain of the select transistor ST1 is connected to the associated bit line BL. The source of the select transistor ST1 is connected to one end of the memory cells MC0, . . . , and MCn−1 connected in series. The drain of the select transistor ST2 is connected to the other end of the memory cells MC0, . . . , and MCn−1 connected in series. The source of the select transistor ST2 is connected to the source line SL.

In the same block BLK, the control gates of the memory cells MC0, MC1, MC2, MC3, . . . , MCn−2, and MCn−1 are respectively connected to the word lines WL0, WL1, WL2, WL3, . . . , WLn−2, and WLn−1, commonly among the plurality of NAND strings. Gates of the select transistors ST1 in the string units SU0, SU1, SU2, SU3, and SU4 are respectively connected to the select gate lines SGD0, SGD1, SGD2, SGD3, and SGD4, commonly among the plurality of NAND strings. The gates of the select transistors ST2 included in the same block BLK are connected to the select gate line SGS commonly among the plurality of NAND strings.

In the circuit configuration of the memory cell array 31 described above, the bit line BL is shared by, for example, the NAND string NS to which the same column address is allocated in each string unit SU. The source line SL is, for example, shared by a plurality of blocks BLK.

Hereinafter, in a certain string unit SU, a set CU of memory cells MC commonly connected to the same word line WL is also referred to as a cell unit CU.

The memory cell MC stores data of one or more bits. A mode in which the memory cell MC stores data of 1 bit is referred to as a single-level cell (SLC) mode. A mode in which the memory cell MC stores data of 2 bits is referred to as a multi-level cell (MLC) mode. A mode in which the memory cell MC stores data of 3 bits is referred to as a triple-level cell (TLC) mode. A mode in which the memory cell MC stores data of 4 bits is referred to as a quad-level cell (QLC) mode. A mode in which the memory cell MC stores data of 5 bits is referred to as a penta-level cell (PLC) mode.

In the present example, one memory cell MC stores 3-bit data. Hereinafter, the 3-bit data is referred to as a lower bit, a middle bit, and an upper bit in order from a lower bit. A set of lower bits held by memory cells belonging to the same cell unit CU is referred to as a lower page (or lower data), a set of middle bits is referred to as a middle page (or middle data), and a set of upper bits is referred to as an upper page (or upper data).

In a case where one memory cell MC can store 3-bit data, three pages are allocated to one word-line WL (one cell unit CU) in one string unit SU. The “page” can also be defined as a part of a memory space formed in the cell unit CU. Writing and reading of data may be performed for each of the pages or each of the cell units CU.

(a-2) Relationship Between Threshold Voltage and Data of Memory Cell

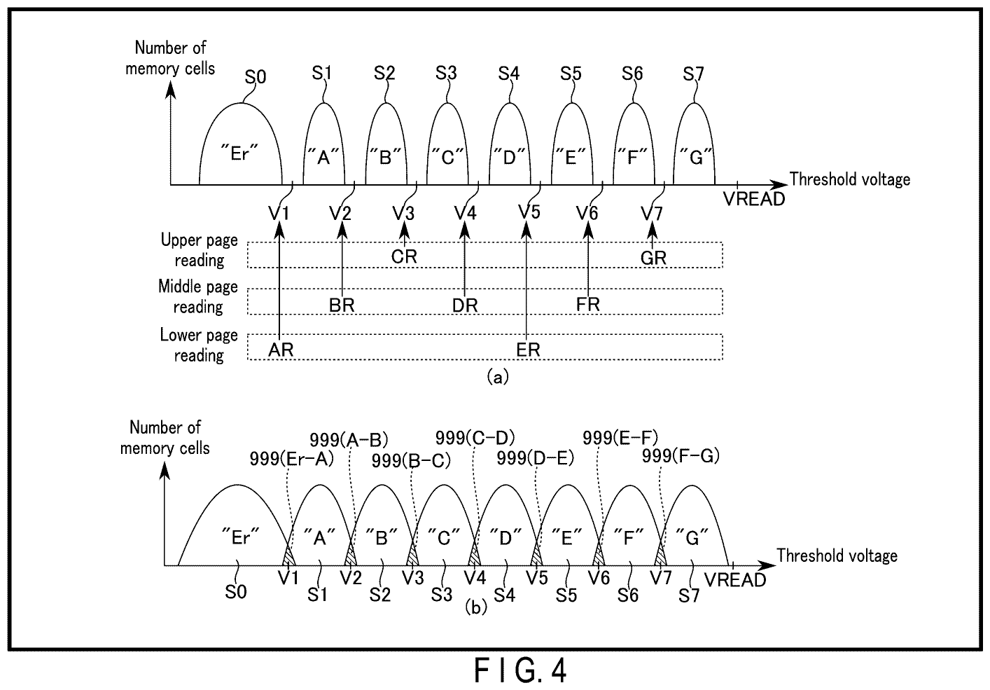

The relationship between the threshold voltage of the memory cell MC and the data stored by the memory cell in the memory system 1 of the present embodiment will be described with reference to FIG. 4.

FIG. 4 is a schematic diagram for illustrating a relationship between a threshold voltage distribution and data to be stored, in a memory cell MC. In FIG. 4, an example of a case where the NAND memory 30 stores data in the TLC mode is illustrated.

(a) of FIG. 4 is a diagram illustrating data that can be taken by each memory cell MC, a threshold voltage distribution, and a voltage used when data is read.

As illustrated in (a) of FIG. 4, in a case where the memory cell MC can store 3-bit data, the memory cell MC can take eight states (threshold voltage distributions) S0, S1, . . . , and S7 according to the threshold voltage Vth. These eight states are referred to as an “Er” state S0, an “A” state S1, a “B” state S2, a “C” state S3, a “D” state S4, an “E” state S5, an “F” state S6, and a “G” state S7 in order from a low threshold voltage.

The read voltage VCGR includes a plurality of voltages (hereinafter, referred to as read levels) V1, V2, V3, V4, V5, V6, and V7 according to the page to be a read target. The read level is a voltage for determining whether the threshold voltage of the memory cell MC is equal to or higher than a certain voltage or lower than the certain voltage. The memory cell MC is turned on or off by the application of the read level.

The threshold voltage of the memory cell MC in the “Er” state S0 is less than the read level V1 and corresponds to an erase state of data. The threshold voltage of the memory cell MC in the “A” state S1 is equal to or higher than the read level V1 and lower than the read level V2. The threshold voltage of the memory cell MC in the “B” state S2 is equal to or higher than the read level V2 and lower than the read level V3. The threshold voltage of the memory cell MC in the “C” state S3 is equal to or higher than the read level V3 and lower than the read level V4. The threshold voltage of the memory cell MC in the “D” state S4 is equal to or higher than the read level V4 and lower than the read level V5. The threshold voltage of the memory cell MC in the “E” state S5 is equal to or higher than the read level V5 and lower than the read level V6. The threshold voltage of the memory cell MC in the “F” state S6 is equal to or higher than the read level V6 and lower than the read level V7. The threshold voltage of the memory cell MC in the “G” state S7 is equal to or higher than the read level V7 and lower than the voltage VREAD. A relationship between the read level V1 through the read level V7 and the voltage VREAD is V1<V2<V3<V4<V5<V6<V7<VREAD.

Among the eight states S0, . . . , and S7 distributed in this manner, the “G” state S7 is the state in which the threshold voltage of the memory cell is the highest. Each of the states S0, . . . , and S7 has a range of voltage values associated with the corresponding data. The states S1, . . . , and S7 from “A” to “G” are referred to as program states.

The voltage VREAD is, for example, a voltage applied to a word line (non-selected word line) WL not to be a read target during the read operation. In a case where the voltage VREAD is applied to the memory cell MC, the memory cell MC is turned on regardless of the data stored in the memory cell MC.

The threshold voltage distribution is implemented by writing data of 3 bits (3 pages) including the lower bit, the middle bit, and the upper bit to the memory cell MC in the memory cell array 31. An example of the relationship between the state of the threshold voltage and the upper bit, the middle bit, and the lower bit is as follows.
“Er” state: “111” (represented in the order of “upper/middle/lower”)
“A” state: “110”
“B” state: “100”
“C” state: “000”
“D” state: “010”
“E” state: “011”
“F” state: “001”
“G” state: “101”

As described above, only 1 bit of 3 bits changes between data corresponding to two adjacent states in the threshold voltage distribution.

A voltage corresponding to a boundary at which the value (“0” or “1”) of the lower bit changes is used to read the lower bit of the memory cell MC. A voltage corresponding to a boundary at which the value of the upper bit changes is used to read the upper bit of the memory cell MC. A voltage corresponding to a boundary at which the value of the middle bit changes is used to read the middle bit of the memory cell MC. Details will be described below.

In order to read the lower bits of the memory cell MC, the NAND memory 30 reads the lower page of the cell unit CU. As illustrated in (a) of FIG. 4, reading of the lower page is executed using a read level V1 for distinguishing between the “Er” state S0 and the “A” state S1 and a read level V5 for distinguishing between the “D” state S4 and the “E” state S5 as the read voltages.

In order to read the middle bits of the memory cell MC, the NAND memory 30 reads the middle page of the cell unit CU. Reading of the middle page is executed using a read level V2 for distinguishing between the “A” state S1 and the “B” state S2, a read level V4 for distinguishing between the “C” state S3 and the “D” state S4, and a read level V6 for distinguishing between the “E” state S5 and the “F” state S6 as the read voltages.

In order to read the upper bits of the memory cell MC, the NAND memory 30 reads the upper page of the cell unit CU. Reading of the upper page is executed using a read level V3 for distinguishing between the “B” state S2 and the “C” state S3 and a read level V7 for distinguishing between the “F” state S6 and the “G” state S7 as the read voltages.

The memory cell MC in the erase state is identified by the reading using the read level V1.

Hereinafter, reading (determination) using the read level V1 is also referred to as AR reading. Similarly to this, readings using the read levels V2, V3, V4, V5, V6, and V7 are referred to as BR reading, CR reading, DR reading, ER reading, FR reading, and GR reading, respectively.

(b) of FIG. 4 is a diagram for illustrating the state of the threshold voltage distribution of the memory cell MC.

When time elapses after data is written, an error (hereinafter, this error-causing stress is referred to as data retention or data retention stress) occurs in which a threshold voltage distribution (state) moves due to interference between memory cells. During the write operation and the read operation of the NAND memory 30, unintended movement of the threshold voltage distribution (hereinafter, respectively referred to as a program disturb and a read disturb) may occur.

The characteristics of the plurality of memory cells MC in the memory cell array 31 tend to have variations. For example, the variation amount and the change time (writing speed) of the threshold voltage of the memory cell MC with respect to a program voltage of a certain value have variations. Due to these variations, when a program voltage of a certain voltage value is applied, a memory cell that has reached a certain threshold voltage and a memory cell MC that has not reached a certain threshold voltage are mixed in the plurality of memory cells MC that are write targets. Therefore, in the program operation, an error may occur in which the threshold voltage of the memory cell MC moves to a state higher than the state corresponding to the data to be written.

For example, a phenomenon in which the threshold voltage of the memory cell decreases may occur after data is written. Due to this phenomenon, the threshold voltage of the memory cell after data is written may change from a value corresponding to data to be stored according to the characteristics of the memory cell (for example, data retention characteristics). It should be noted that the change amount of the threshold voltage in the phenomenon in which the threshold voltage decreases after the data is written has variations according to the characteristics of the memory cell.

When the threshold voltage distributions accompanying such various variable factors change, adjacent threshold voltage distributions may overlap.

Since the adjacent threshold voltage distributions overlap, the read operation using the voltages V1, V2, V3, . . . , V6, and V7 may not correctly read the data in the memory cell MC from the memory cell MC having the threshold voltage in the area 999 where the distributions overlap.

For example, in a case where the threshold voltage distribution S1 of the “A” state and the threshold voltage distribution S2 of the “B” state overlap with each other, among the memory cells MC of the threshold voltage distribution S1 of the “A” state, the memory cell MC having a threshold voltage higher than the read level V2 may be erroneously read as the “B” state S2, and among the memory cells MC of the threshold voltage distribution S2 of the “B” state, the memory cell MC having a threshold voltage lower than the read level V2 may be erroneously read as the “A” state S1. As described above, in a case where the number of erroneously read bits (the number of error bits) exceeds the number of correctable bits of the ECC circuit 160, the memory controller 10 fails in reading correct data from the NAND memory 30.

The memory system 1 of the present embodiment detects an error (error bit) included in the read data, inside the NAND memory 30. The memory system 1 of the present embodiment calculates, inside the NAND memory 30, a dynamic shift value for setting a read voltage (read level) more suitable for the state in the memory cell array 31 during the read operation based on the detection result of the error.

Hereinafter, the read operation of calculating, inside the NAND memory 30, the dynamic shift value of the read level is referred to as an automatic adjustment read operation. In addition, the read operation in which the dynamic shift value is not calculated is referred to as a normal read operation.

(a-3) Overview of Calculation of Dynamic Shift Value of Read Level

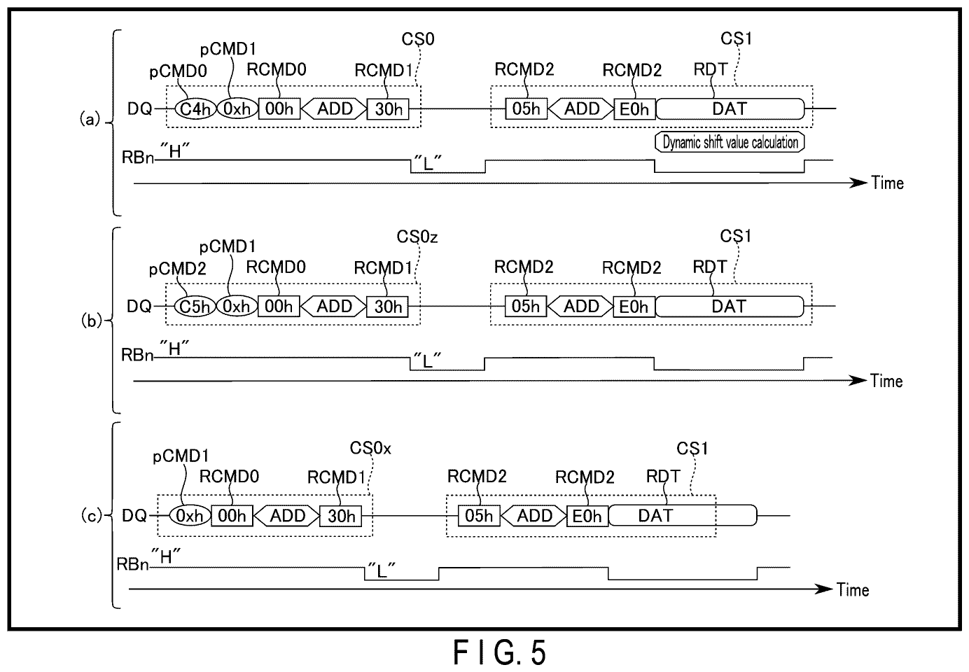

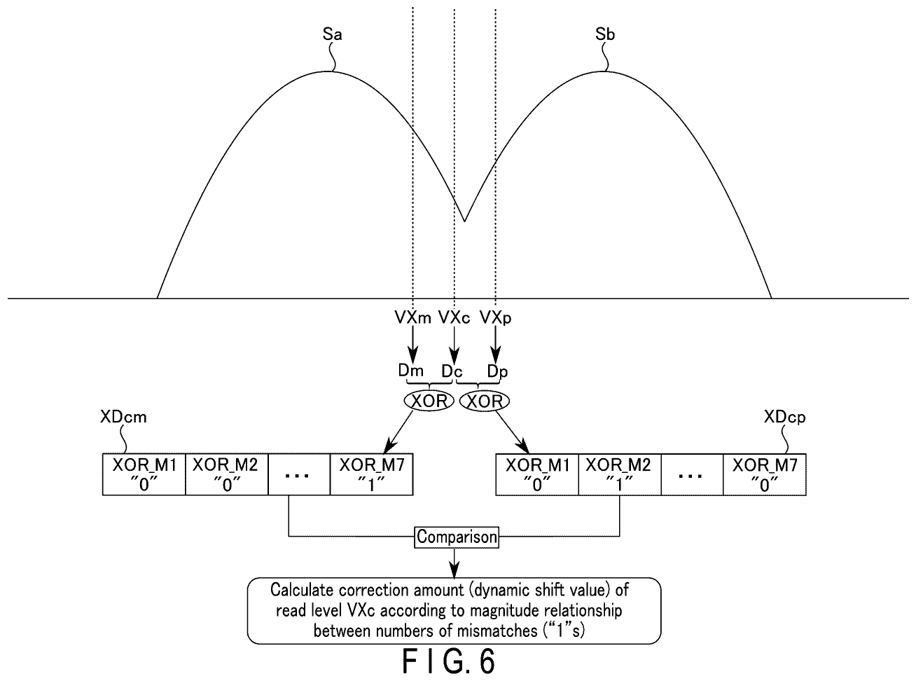

An overview of the calculation of the dynamic shift value of the read level in the memory system 1 of the present embodiment will be described with reference to FIGS. 5 and 6.

(a-3-1) Command Sequence

FIG. 5 is a sequence diagram illustrating a command set used to read data from the NAND memory 30 in the memory system 1 of the present embodiment.

In the memory system 1 of the present embodiment, the memory controller 10 executes calculation of the dynamic shift value of the read level, inside the NAND memory 30. The calculation of the dynamic shift value of the read level is based on the detection of the error of the data acquired in the read operation and the detection result of the error. In this case, the memory controller 10 commands the NAND memory 30 to perform an automatic adjustment read operation.

When the command of the automatic adjustment read operation is issued, the memory controller 10 sends the command sets CS0 and CS1 in (a) of FIG. 5 to the NAND memory 30.

As illustrated in (a) of FIG. 5, the command set CS0 includes prefix commands pCMD0 and pCMD1, a command RCMD0, an address ADD, and a command RCMD1. The command set CS0 is a set of signals for commanding the NAND memory 30 to perform an automatic adjustment read operation.

A prefix command pCMD0 of “C4h” is sent from the memory controller 10 to the NAND memory 30. The prefix command pCMD0 of “C4h” is a command for instructing the NAND memory 30 to perform read operation on data using: reading of data using a certain normal standard read level, reading of data using a read level offset to a voltage side lower than the certain normal read level, and reading of data using a read level offset to a voltage side higher than the certain normal read level.

The certain normal standard read level is hereinafter referred to as a standard read level. The read level offset to a voltage side lower than the certain normal read level is hereinafter referred to as a minus read level. The read level offset to a voltage side higher than the certain normal read level is hereinafter referred to as a plus read level. In addition, the reading of data using the standard read level is hereinafter referred to as standard reading. The reading of data using the minus read level is hereinafter referred to as minus reading. The reading of data using the plus read level is hereinafter referred to as plus reading.

After the prefix command pCMD0 of “C4h” is transmitted, a prefix command pCMD1 for designating a page is sent from the memory controller 10 to the NAND memory 30. The prefix command pCMD1 of “01h” is a command for designating the lower page. The prefix command pCMD1 of “02h” is a command for designating the middle page. The prefix command pCMD1 of “03h” is a command for designating the upper page.

After the transmission of the prefix commands pCMD0 and pCMD1, the command RCMD0 of “00h” is sent from the memory controller 10 to the NAND memory 30. The command RCMD0 of “00h” is a command for notifying the NAND memory 30 of the execution of the read operation on the memory cell array 31.

The address ADD is sent from the memory controller 10 to the NAND memory 30 after the transmission of the command RCMD0. The address ADD is indicated by, for example, a data size of five cycles.

The command RCMD1 of “30h” is transmitted from the memory controller 10 to the NAND memory 30 after the transmission of the address ADD. The command RCMD1 of “30h” is a command for instructing the NAND memory 30 to start a read operation.

In response to the command RCMD1 of “30h”, the ready/busy control circuit 34 changes the signal level of the ready/busy signal RBn from the “H” level to the “L” level.

The NAND memory 30 executes standard reading, minus reading, and plus reading depending on the command set CS0 including the prefix command pCMD0. The NAND memory 30 corrects each read level by adding a shift value to a default value of each read level. The shift value includes at least a static shift value and a designated shift value.

When the read operation in the NAND memory 30 is completed, the ready/busy control circuit 34 changes the signal level of the ready/busy signal RBn from the “L” level to the “H” level.

The memory controller 10 transmits the command set CS1 to the NAND memory 30 after transmitting the command set CS0 in order to command the output of data from the NAND memory 30 to the memory controller 10. The command set CS1 is a set of signals for commanding the NAND memory 30 to output data obtained by the read operation to the memory controller 10.

The command set CS1 includes a command RCMD2, an address ADD, and a command RCMD3.

After the signal level of the ready/busy signal RBn changes from the “L” level to the “H” level, the command RCMD2 of “05h” is sent from the memory controller 10 to the NAND memory 30. The command RCMD2 of “05h” is a command for instructing the NAND memory 30 to output data to the memory controller 10.

The address ADD is sent from the memory controller 10 to the NAND memory 30 after the transmission of the command RCMD2. The address ADD includes the same address value as the address ADD included in the command set CS0.

After the transmission of the address ADD, the command RCMD3 of “EOh” is sent from the memory controller 10 to the NAND memory 30. The command RCMD3 of “EOh” is a command for instructing the NAND memory 30 to start outputting data to the memory controller 10.

In response to the command RCMD3 of “EOh”, the ready/busy control circuit 34 changes the signal level of the ready/busy signal RBn from the “H” level to the “L” level.

When the NAND memory 30 receives the command set CS1 for outputting the read data, the data of the predetermined data latch DL holding the data read by the standard read level is transferred to the data latch (XDL) for external input/output. In the NAND memory 30, the data DAT in the data latch (XDL) is output as read data RDT from the input/output circuit 32 to the memory controller 10.

As described above, the NAND memory 30 transmits the read data RDT to the memory controller 10 according to the command set CS1.

As a result, the read data is transmitted to the memory controller 10.

In the memory system 1 of the present embodiment, the NAND memory 30 calculates the dynamic shift value of the read level used for the read operation (standard read) in parallel with the transfer of the read data RDT from the NAND memory 30 to the memory controller 10. Accordingly, the read level used for the read operation according to the command sets CS0 and CS1 is corrected. That is, the read level of the normal read operation in and after the automatic adjustment read operation is set using the calculated dynamic shift value.

In addition, the NAND memory 30 stores the calculated dynamic shift value in the register for a dynamic shift value of the setting information register 350. It should be noted that the calculated dynamic shift value may be stored in a register for a temporary code or a feature register used by a set feature command.

In addition, in a case where the calculated dynamic shift value is stored in the register for a dynamic shift value when the NAND memory 30 receives the prefix command “C4h”, the dynamic shift value is added to the shift value to correct each read level.

(b) of FIG. 5 illustrates command sets CS0z and CS1 during the execution of the automatic adjustment read operation in the memory system 1 of the present embodiment.

As illustrated in (b) of FIG. 5, in a case where the automatic adjustment read operation is executed, the memory controller 10 transmits a command set CS0z including a prefix command pCMD2 of “C5h” to the NAND memory 30.

The memory controller 10 transmits the prefix command pCMD2 of “C5h” to the NAND memory 30 as a head command of the command set CS0z. The prefix command pCMD2 of “C5h” is a command for instructing the NAND memory 30 to perform a data read operation using the normal read level, the minus read level, and the plus read level. Thereafter, the memory controller 10 sequentially transmits the prefix command pCMD1, the command RCMD0, the address ADD, and the command RCMD1 to the NAND memory 30.

The NAND memory 30 executes standard reading, minus reading, and plus reading depending on the command set CS0z including the prefix command pCMD2. The NAND memory 30 sets each read level by adding a shift value to a default value of each read level. The shift value includes a static shift value and a designated shift value. In addition, at this time, even in a case where the calculated dynamic shift value is stored in the register for a dynamic shift value, the NAND memory 30 does not include the dynamic shift value in the shift value.

After the signal level of the ready/busy signal RBn changes from the “L” level to the “H” level, the memory controller 10 sends the command set CS1 to the NAND memory 30 in order to command the output of data.

The NAND memory 30 transmits the read data RDT to the memory controller 10 according to the command set CS1.

In a case of receiving a command for giving an instruction that a normal read operation be performed after receiving the prefix command pCMD2 of “C5h”, the NAND memory 30 corrects the read level by the dynamic shift value adjusted by the prefix command pCMD2 of “C5h”. It should be noted that the dynamic shift value adjusted by the prefix command pCMD2 of “C5h” is used only for the first command for giving an instruction that the normal read operation be performed received after the prefix command pCMD2 of “C5h”. For the second command for giving an instruction that the normal read operation be performed received after the prefix command pCMD2 of “C5h”, the dynamic shift value adjusted by the prefix command pCMD2 of “C5h” is not used, and the dynamic shift value stored in the register for a dynamic shift value is used. In other words, in a case where a dynamic shift value adjusted by the prefix command pCMD0 of “C4h” before the prefix command pCMD2 is present, the dynamic shift value adjusted by the prefix command pCMD0 of “C4h” is used for the read command other than immediately after the prefix command pCMD2 of “C5h”.

In addition, the NAND memory 30 stores the calculated dynamic shift value in the register for a dynamic shift value of the setting information register 350. It should be noted that the calculated dynamic shift value may be stored in a register for a temporary code or a feature register used by a set feature command.

Accordingly, the memory system 1 of the present embodiment can execute the read operation using a more suitable read level.

(c) of FIG. 5 illustrates command sets CS0x and CS1 during the execution of the normal read operation in the memory system 1 of the present embodiment.

As illustrated in (c) of FIG. 5, in a case where the dynamic shift value of the read level is not calculated inside the NAND memory 30 during the read operation (in a case where the normal read operation is executed), the memory controller 10 transmits a command set CS0x not including the prefix command pCMD0 of “C4h” to the NAND memory 30. Accordingly, the NAND memory 30 executes the read operation using only the standard read level according to the command set CS0x. The NAND memory 30 outputs the read data RDT to the memory controller 10 according to the command set CS1.

For example, in the normal read operation, in a case where the dynamic shift value related to the corresponding address ADD is stored in the setting information register 350, the read level is corrected using the shift value including the dynamic shift value calculated by the automatic adjustment read operation. The threshold voltage of the memory cell MC can be determined by the corrected read level.

Accordingly, the memory system 1 of the present embodiment can execute the read operation using a more suitable read level.

It should be noted that in a case where the dynamic shift value related to the corresponding address ADD is not stored in the setting information register 350, the NAND memory 30 sets the read level using the shift value not including the dynamic shift value, and executes the read operation.

(a-3-2) Automatic Adjustment Read Operation

FIG. 6 is a schematic diagram for illustrating an overview of the reading of data from the NAND memory 30 according to the command set CS0 in (a) of FIG. 5 in the memory system 1 of the present embodiment.

In FIG. 6, two adjacent threshold voltage distributions Sa and Sb among a plurality of threshold voltage distributions corresponding to data stored in the NAND memory 30 are extracted and illustrated.

In the NAND memory 30, during long-term data storage, the threshold voltage distribution related to data in the memory cell array 31 moves to the low voltage side due to the data retention stress. In the present embodiment, it is assumed that threshold voltage distributions (and a plurality of read levels) of a certain page move in the same direction.

As described above, during the read operation of the NAND memory 30, in addition to the standard reading of reading data using the standard read level (read voltage) related to a certain threshold voltage distribution according to the prefix command pCMD0, the memory system 1 of the present embodiment executes minus reading of reading data using a read level slightly lower than the standard read level and plus reading of reading data using a read level slightly higher than the standard read level.

A plurality of minus read levels are set for the plurality of respective standard read levels. A plurality of plus read levels are set for the plurality of respective standard read levels. Hereinafter, the standard read level is referred to as VXc, the minus read level is referred to as VXm, and the plus read level is referred to as VXp.

The difference (offset value: R_ViOstM) between the minus read level and the standard read level is set to about 20% of the voltage difference between the adjacent standard read levels. For example, the difference between the minus read level and the standard read level is about 10 DAC. For example, regarding the read level VX (VXc, VXm, and VXp) between the threshold voltage distribution Sa and the threshold voltage distribution Sb, there is a relationship expressed by the following Formula (FA) between the minus read level VXm and the standard read level VXc.

$$VXm = Vxc - 10 DAC \qquad ( FA )$$

The difference between the standard read level VXc and the plus read level VXp (offset value: R_ViOstP) is also set to about 10 DAC. For example, regarding the read level VX between the threshold voltage distribution Sa and the threshold voltage distribution Sb, there is a relationship expressed by the following Formula (FB) between the plus read level VXp and the standard read level VXc.

$$VXp = VXc + 10 DAC \qquad ( FB )$$

It should be noted that “DAC” corresponds to a setting value (digital value) stored in a register inside the NAND memory 30 which is used to set a voltage value (analog value) of a charge pump that generates a voltage applied to the word line WL or the like inside the NAND memory 30. For example, 1 DAC corresponds to 10 mV. However, the relationship between the DAC value and the analog value of the voltage differs according to the specification of the NAND memory 30. Depending on the specification of the memory system, 1 DAC may correspond to 15 mV or the like.

For example, the offset value for each read level at the minus read level and the plus read level is set in advance by a set feature command sequence (alternatively, temporary code designation) or the like. The offset value of the read level is managed in the table TBL of the memory controller 10, or the register circuit 35 (or the ROM area) of the NAND memory 30. Accordingly, it is possible to execute data reading using a voltage value lower than the voltage value of the standard read level or a voltage value higher than the voltage value of the standard read level. A voltage value lower than the voltage value of the standard read level is, that is, a minus read level. A voltage value higher than the voltage value of the standard read level is, that is, a plus read level.

In the present embodiment, data is read using the minus read level VXm and the plus read level VXp having voltage values offset from the voltage value of the standard read level. As a result, the memory system 1 of the present embodiment reduces the number of error bits of the data read by the adjustment (offset) of the read level VX even if the threshold voltage of the memory cell MC slightly moves due to the stress applied to the NAND memory 30.

The standard read level VXc related to the i-th threshold voltage distribution is represented as a standard read level Vic. In the memory system 1 of the present embodiment, when data written in the TLC mode is read, the NAND memory 30 sets the standard read level Vic related to the i-th threshold voltage distribution based on the setting value of the register (R_ViSlfTr) of the setting information register 350 as expressed in the following Formula (FC). It should be noted that i is an integer of 1 or more and 7 or less.

$$Vic = Vis + Vi\_ 0 = R\_Vit + R\_Viss + R\_VislfTr + Vi\_ 0 \qquad ( FC )$$

Similarly to this, the minus read level Vim is set as in the following Formula (FD).

$$Vim = Vic - R\_ViOstM = ( R\_Vit + R\_ViSS + R\_ViSlfTr + Vi\_ 0 ) - R\_ViOstM \qquad ( FD )$$

In addition, the plus read level Vip is set as in the following Formula (FE).

$$Vip = Vic - R\_ViOstP = ( R\_Vit + R\_ViSS + R\_ViSlfTr + Vi\_ 0 ) - R\_ViOstP \qquad ( FE )$$

Data acquired by the NAND memory 30 using a plurality of standard read levels VXc is referred to as standard read data Dc. The standard read data Dc is data for one page and is read data RDT. Data obtained by determining on/off of the memory cell MC using one of the standard read levels VXc is referred to as determination result data Dic. That is, the data read using the standard read level related to the i-th threshold voltage distribution is represented as the determination result data Dic. Data acquired by the NAND memory 30 using a plurality of minus read levels VXm is referred to as minus read data Dm. The minus read data Dm is data for one page. The data read using the minus read level related to the i-th threshold voltage distribution is represented as the determination result data Dim.

In the NAND memory 30, the error bit detection circuit 50 executes an exclusive OR operation (XOR operation) for each identical memory cell MC on the standard read data Dc and the minus read data Dm. That is, for the specific memory cell MC, the XOR operation is performed on the result of the determination performed at the minus read level and the result of the determination performed at the standard read level. Hereinafter, the data indicating the result of the XOR operation on the standard read data Dc and the minus read data Dm is referred to as XOR operation data XDcm. The XOR operation data XDcm related to the i-th threshold voltage distribution to be described below is represented as XOR operation data XDicm.

The value of the result of the XOR operation for each memory cell MC in the standard read data Dc and the minus read data Dm is “0” if the values read from the same memory cell MC of the two pieces of data Dc and Dm match each other, and is “1” if the values read from the same memory cell MC do not match each other.

The standard read data Dc and the minus read data Dm are data for one page (for example, data of about 18 kByte). Therefore, the data indicating the result of the XOR operation of the standard read data Dc and the minus read data Dm is also data for one page.

Data acquired by the NAND memory 30 using a plurality of plus read levels VXp is referred to as plus read data Dp. The plus read data Dp is data for one page. The data read using the plus read level related to the i-th threshold voltage distribution is represented as the plus determination result data Dip.

In the NAND memory 30, the error bit detection circuit 50 executes an XOR operation for each identical memory cell MC on the standard read data Dc and the plus read data Dp. The data indicating the result of the XOR operation on the standard read data Dc and the plus read data Dp is referred to as XOR operation data XDcp. The XOR operation data XDcp related to the i-th threshold voltage distribution to be described below is represented as XOR operation data XDicp.

The value of the result of the XOR operation for each memory cell MC in the standard read data Dc and the plus read data Dp is “0” if the values read from the same memory cell MC of the two pieces of data Dc and Dp match each other, and is “1” if the values read from the same memory cell MC do not match each other.

The plus read data Dp is data for one page. Therefore, the data indicating the result of the XOR operation of the standard read data Dc and the plus read data Dp is also data for one page.

The determination result data Dic, Dim, and Dip of the respective read levels Vic, Vim, and Vip related to each of the threshold voltages are stored in the corresponding data latches among the plurality of data latches DL. Similarly to this, data obtained by various types of operational processing for the read data and the determination result data is stored in the corresponding data latch among the plurality of data latches DL.

As described above, the input/output units of the data of the input/output circuit 32 (hereinafter referred to as I/O units) are 8 bits.

The error bit detection circuit 50 compares the number of “1”s of the respective bits XOR_M0, XOR_M1, . . . , and XOR_M7 of the data in I/O units in the XOR operation data XDcm of the standard read data Dc and the minus read data Dm with the number of “1”s of the respective bits XOR_PC, XOR_P1, . . . , and XOR_P7 of the data in I/O units in the XOR operation data XDcp of the standard read data Dc and the plus read data Dp. That is, the error bit detection circuit 50 compares the number of mismatches between the bits of the standard read data Dc and the bits of the minus read data Dm with the number of mismatches between the bits of the standard read data Dc and the bits of the plus read data Dp.

It should be noted that the number of changes from “0” to “1” or changes from “1” to “0” of the value of each bit of the standard read data Dc in each of the threshold voltage distributions S2, S4, and S6 in the reading of the middle page is 0 to 1. Correspondingly to this, a case where the value of the detection result (XOR operation data) of the error bit in each of the determination results of the threshold voltage distributions S2, S4, and S6 changes from “0” to “1” occurs only when the determination based on the read level in which the value of the standard read data Dc changes is performed. That is, a case where the value of a certain bit of the detection result changes from “0” to “1” is a case where an error occurs in any one of the threshold voltage distribution S2, S4, or S6. Therefore, the number of times the value of the detection result changes from “0” to “1” is at most once.

The error bit detection circuit 50 compares the XOR operation data XDcm related to the minus read data Dm with the XOR operation data XDcp related to the plus read data Dp.

For example, the error bit detection circuit 50 executes calculation processing using the respective bits XOR_M0, . . . , XOR_M7, XOR_PC, . . . , and XOR_P7 of the data in I/O units in the XOR operation data XDcm and the XOR operation data XDcp. For example, the error bit detection circuit 50 calculates a difference Delta_M-P between the bits XOR_M0, . . . , and XOR_M7 of the data in I/O units in the XOR operation data XDcm related to the minus read data Dm and the bits XOR_P0, . . . , and XOR_P7 of the data in I/O units in the XOR operation data XDcp related to the plus read data Dp as in the following Formula (FF).

$$Delta\_M - P = ( XOR\_M 0 + XOR\_M 1 + … + XOR\_M 7 ) - ( XOR\_P 0 + XOR\_P 1 + … + XOR\_P 7 ) \qquad ( FF )$$

The correction amount calculation circuit 52 calculates the dynamic shift value of the read level based on the positive or negative (or the positive or negative and the magnitude of the value) of the difference Delta_M-P acquired by the error bit detection circuit 50.

For example, in a case where the difference Delta_M-P is larger than 0 (zero) (in a case where Delta_M-P>0), it is indicated that the number of data mismatches between the minus read data Dm and the standard read data Dc is larger than the number of data mismatches between the plus read data Dp and the standard read data Dc. Therefore, in a case where Delta_M-P>0, the correction amount calculation circuit 52 calculates the dynamic shift value so that the read level is shifted to the plus side (higher voltage side). The NAND memory 30 adds the calculated dynamic shift value to the shift value and sets the read level.

For example, in a case where the difference Delta_M-P is smaller than 0 (zero) (in a case where Delta_M-P<0), it is indicated that the number of data mismatches between the plus read data Dp and the standard read data Dc is larger than the number of data mismatches between the minus read data Dm and the standard read data Dc. Therefore, in a case where Delta_M-P<0, the correction amount calculation circuit 52 calculates the dynamic shift value so that the read level is shifted to the minus side (lower voltage side). The NAND memory 30 adds the calculated dynamic shift value to the shift value and sets the read level.

Accordingly, the memory system 1 of the present embodiment reduces the number of error bits of the read data by the read operation performed after the correction of the read level as an average as compared with that before the correction.

For example, when the intersection of the two threshold voltage distributions Sa and Sb is set to the read level, the error of the read data is minimized. In the example in FIG. 6, the intersection of the two threshold voltage distributions Sa and Sb is positioned on the higher voltage side than the currently set standard read level VXc. Therefore, it is desirable for the reduction of the number of error bits that the standard read level VXc be shifted to a higher voltage side than the current standard read level. In the present example, when the calculated XOR operation data XDcm is compared with the XOR operation data XDcp, the number of “1”s is smaller in the XOR operation data XDcp. That is, the difference Delta_M-P is greater than zero. Accordingly, the NAND memory 30 sets the dynamic shift value so as to shift the standard read level VXc related to the threshold voltage distributions Sa and Sb to the higher voltage side than the current standard read level.

Also in each threshold voltage distribution other than the threshold voltage distributions Sa and Sb, in a case where the number of mismatches at the minus read level tends to be larger than the number of mismatches at the plus read level, the difference Delta_M-P in each threshold voltage distribution is larger than zero. Also in this case, the dynamic shift value may only need to be set so that the read level of each threshold voltage distribution is shifted to the higher voltage side than the standard read level.

The NAND memory 30 stores the set dynamic shift value in the register for a dynamic shift value of the setting information register 350. It should be noted that the calculated dynamic shift value may be stored in a register for a temporary code or a feature register used by a set feature command.

It should be noted that in a case where a plurality of read levels are used to read the selected page, as described below, it is more preferable to finally use the number of “1”s (the number of mismatches) included in the data in which the result of the XOR operation for each read level is accumulated by the OR operation for the calculation of the dynamic shift value in order to improve the efficiency of the calculation of the dynamic shift value.

For example, a certain data latch DL (for example, the data latch GDL) stores data in which data obtained by performing an XOR operation on the standard read data Dc and the minus read data Dm for each read level (threshold voltage distribution) is accumulated by an OR operation. In other words, the certain data latch DL stores data obtained by further performing an OR operation for a plurality of read levels on the data obtained by performing an XOR operation on the standard read data Dc and the minus read data Dm for each read level. The data is bitmap data indicating the presence or absence of a mismatch between the standard read data Dc and the minus read data Dm in each threshold voltage distribution.

Similarly to this, another data latch DL (for example, the data latch HDL) stores data in which data obtained by performing an XOR operation on the standard read data Dc and the plus read data Dp for each read level is accumulated by an OR operation. The data is bitmap data indicating the presence or absence of a mismatch between the standard read data Dc and the plus read data Dp in each threshold voltage distribution.

Then, the number of “1”s included in the accumulated data in a certain data latch is compared with the number of “1”s included in the accumulated data in another data latch. Based on the comparison result, the dynamic shift value is set so that the standard read level is shifted in a direction corresponding to data with the smaller number of “1”s. Accordingly, the NAND memory 30 adjusts the read level so that the number of error bits during the subsequent read operation decreases.

As described above, the memory system 1 of the present embodiment improves the reliability of data reading from the NAND memory 30.

### (b) Operation Example

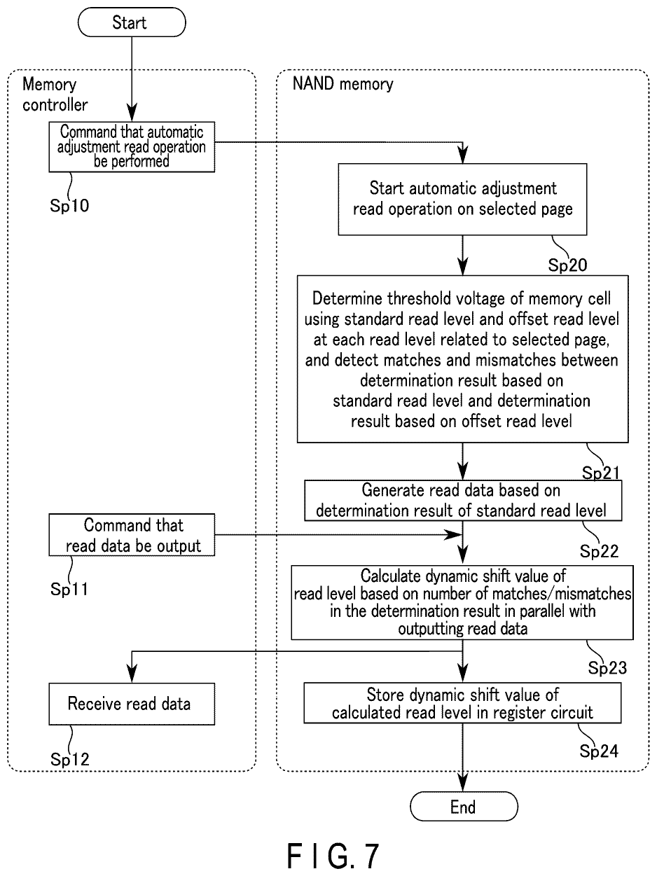

An operation example of the memory system 1 of the present embodiment will be described with reference to FIGS. 7 to 20. An operation example of the memory system 1 of the present embodiment relates to a method for controlling the reading of data of the memory system 1 and a method for controlling the reading of data of a memory device (NAND memory) 30 of the present embodiment.

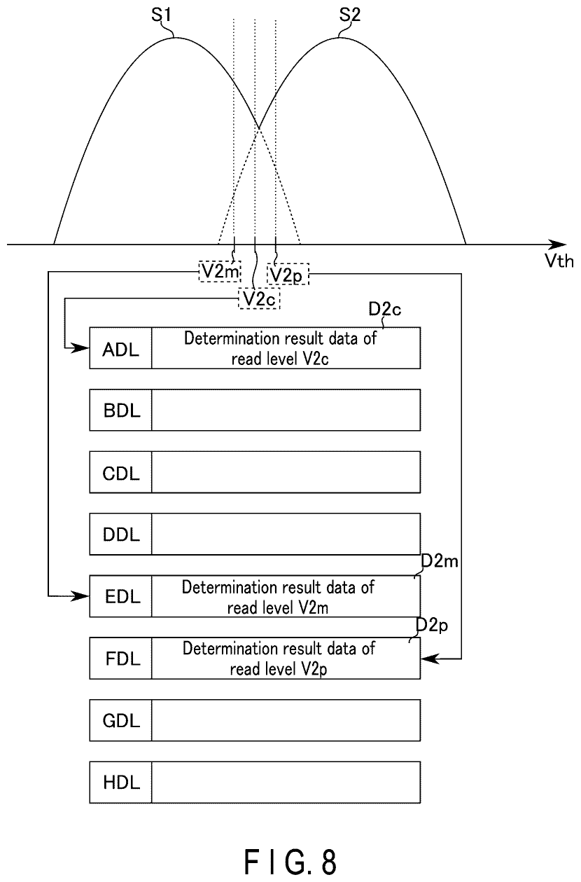

FIG. 7 is a flowchart illustrating an operation example of the memory system 1 of the present embodiment. FIGS. 8 to 18 are schematic diagrams for illustrating an operation example of the memory system 1 of the present embodiment.

(b-1) <Sp10>

As illustrated in FIG. 7, in the memory system 1 of the present embodiment, the memory controller 10 commands the NAND flash memory 30 to perform an automatic adjustment read operation. The memory controller 10 sends the command set CS0 in (a) of FIG. 5 to the NAND memory 30.

(b-2) <Sp20>

The NAND memory 30 receives a prefix command pCMD0 of “C4h”, a prefix command pCMD1, a command (00h) RCMD0, an address ADD for 5 cycles, and a command (30h) RCMD1.

Accordingly, the NAND memory 30 starts the automatic adjustment read operation. The NAND memory 30 reads various types of setting information for a read operation from the register circuit 35. The NAND memory 30 sets voltage values of a plurality of read levels used for the automatic adjustment read operation based on the setting information.

In the following, a case where the reading of the middle page is instructed by the prefix command pCMD1 of “02h” will be described.

(b-3) <Sp21>

In the NAND memory 30, the sequencer 36 executes the read operation on the area indicated by the address ADD in the memory cell array 31 based on the received command set.

The NAND memory 30 determines the threshold voltage of the memory cell MC using the standard read level and the offset read level at each of one or more read levels related to the selected page.

For example, in the automatic adjustment read operation (and the normal read operation), the state of the threshold voltage of the memory cell MC by each read level is determined in order from the lower threshold voltage (lower state). Data indicating the determination result of each read level (hereinafter referred to as determination result data) is sequentially stored in the data latch DL. Various types of operational processing are executed using the data in the data latch DL. Data transfer between the data latches DL and data storage in the data latch DL are performed by the internal processing of the NAND memory 30.

In a case where the normal read operation of the middle page (the read operation in which the dynamic shift value is not calculated) is executed, on and off of the plurality of memory cells MC included in the selected address (selected word line WL) are determined using the standard read level V2 (V2c), the standard read level V4 (V4c), and the standard read level V6 (V6c). The determination result data of each of the read levels V2, V4, and V6 is stored in the corresponding data latch DL in the data latch circuit 40.

During the execution of the automatic adjustment read operation, the NAND memory 30 executes the determination of the threshold voltages of the memory cell at a plurality of read levels corresponding to the selected page according to the setting of the memory system 1 using the standard read level and the offset read level (the minus read level and the plus read level).

For example, each read level is set as follows based on the setting value of the setting information in the register circuit 35.

The default value of the standard read level V2c related to the threshold voltage distribution S2 in the standard reading is denoted as “V2_0”. The shift value is denoted as “V2S”, the designated shift value is denoted as “R_V2SS” (or V2SS), the static shift value is denoted as “R_V2t” (or V2t), and the dynamic shift value is denoted as “R_V2d” (or V2d). The shift value V2S is a value obtained by adding the designated shift value “R_V2SS”, the static shift value“R_V2t”, and the dynamic shift value “R_V2d” together. The standard read level V2c is set by adding the shift value to the default value “V2_0”.

In the automatic adjustment read operation, standard reading is performed a plurality of times for each state. The standard read level of the first standard reading is denoted as “V2c_1”, and the standard read level of the N-th standard reading is denoted as “V2c_N”. The dynamic shift value of the first standard reading is denoted as “V2d_1”, and the dynamic shift value of the N-th standard reading is denoted as “V2d_N”. N is an integer of 1 or more. In addition, in the present embodiment, the shift value of the read level in the j-th automatic adjustment read operation is denoted as “V2S_j”. The dynamic shift value of the j-th automatic adjustment read operation is denoted as “V2d_j”. The j is an integer of 1 or more.

The shift value V2S, the static shift value V2t, and the dynamic shift value V2d have the following relationship.

$$V2S\_j = V 2 t + V2d\_j$$

The standard read level V2c and the shift value V2S of the standard reading have the following relationship. In addition, here, the default shift value “V2S_0” is set to 0 (zero) for convenience.

$$V2S\_ 0 = 0$$

$$V2c\_ 0 = V2\_ 0$$

$$V2c\_j = V2c\_ ( j - 1 ) + V2S\_ ( j - 1 ) = ( V2\_ 0 + V2S\_ 0 ) + \sum V2S\_k ,$$

where “ΣV2S_k” is the total sum of the shift values “V2S_0”, “V2S_1”, . . . , and “V2S_(j−1)”. Hereinafter, ΣV2S_k is referred to as a cumulative shift value.

For example, consider the memory system 1 that has completed the automatic adjustment read operation twice. A value obtained by adding the shift value of the read level obtained in the first automatic adjustment read operation to the standard read level for the first standard reading is set as the standard read level for the second standard read operation. That is, a value obtained by adding the cumulative shift value up to the second time to a value obtained by adding the default value of the standard read level and the default shift value is set as the standard read level of the second standard read operation.

The default value of the minus read level V2m related to the threshold voltage distribution S2 in the minus reading is denoted as “V2m_0”.

In the automatic adjustment read operation, minus reading is performed a plurality of times for each state.

The minus read level in the first minus reading is denoted as “V2m_1”, and the minus read level in the N-th minus reading is denoted as “V2m_N”.

The minus read level V2m and the offset value that are related to the threshold voltage distribution S2 in the minus reading have the following relationship.

$$V2m\_j = V2m\_ ( j - 1 ) + V2S\_ ( j - 1 ) = ( V2c\_ ( j - 1 ) - 10 DAC ) + V2S\_ ( j - 1 ) = \{ ( V2\_ 0 + V 2 S ) + \sum V2S\_k \} - 10 DAC = V2c\_j - 10 DAC$$

For example, consider the memory system 1 that has completed the automatic adjustment read operation twice. A value obtained by adding the shift value of the read level obtained in the first automatic adjustment read operation to the minus read level for the first minus reading is set as the minus read level for the second minus read operation. That is, a value obtained by subtracting the offset value of 10 DAC from the value of the second standard read level is set as the minus read level of the second minus read operation.

The default value of the plus read level V2p related to the threshold voltage distribution S2 in the plus reading is denoted as “V2p_0”.

In the automatic adjustment read operation, plus reading is performed a plurality of times for each state. The plus read level in the first plus reading is denoted as “V2p_1”, and the plus read level in the N-th plus reading is denoted as “V2p_N”.

The plus read level V2p and the offset value that are related to the threshold voltage distribution S2 in the plus reading have the following relationship.

$$V2c\_j = V2p\_ ( j - 1 ) + V2S\_ ( j - 1 ) = ( V2c\_ ( j - 1 ) + 10 DAC ) + V2S\_ ( j - 1 ) = \{ ( V2\_ 0 + V 2 S ) + \sum V2S\_k \} + 10 DAC = V2c\_j + 10 DAC$$

For example, consider the memory system 1 that has completed the automatic adjustment read operation twice. A value obtained by adding the shift value of the read level obtained in the first automatic adjustment read operation to the plus read level for the first plus reading is set as the plus read level for the second plus read operation. That is, a value obtained by adding the offset value of 10 DAC to the value of the second standard read level is set as the plus read level of the second plus read operation.

Similarly to the voltage value of each of the read levels V2c, V2m, and V2p related to the threshold voltage distribution S2, the voltage values of the respective read levels are set regarding the threshold voltage distributions S4 and S6.

The default value of the standard read level V4c related to the threshold voltage distribution S4 in the standard reading is denoted as “V4_0”, and the shift value is denoted as“V4S”. The standard read level of the first standard reading in the automatic adjustment read operation is denoted as “V4c_1”.

The standard read level V4c and the shift value that are related to the threshold voltage distribution S4 in the standard reading have the following relationship.

$$V4c\_j = V4c\_ ( j - 1 ) + V 4 S + V4S\_ ( j - 1 ) = ( V4\_ 0 + V 4 S ) + \sum V4S\_k ,$$

where “ΣV4S_k” is the total sum of the shift values “V4S_0”, “V4S_1”, . . . , and “V4S_(j−1)”.

The minus read level V4m and the offset value that are related to the threshold voltage distribution S4 in the minus reading have the following relationship.

$$V4m\_j = V4c\_j - 10 DAC$$

The plus read level V4p and the offset value that are related to the threshold voltage distribution S4 in the plus reading have the following relationship.

$$V4p\_j = V4c\_j + 10 DAC$$

The default value of the standard read level V6c related to the threshold voltage distribution S6 in the standard reading is denoted as “V6_0”, and the shift value is denoted as “V6S”. The standard read level of the first standard reading in the automatic adjustment read operation is denoted as “V6c_1”.

The standard read level and the shift value that are related to the threshold voltage distribution S6 in the normal read operation have the following relationship.

$$V6c\_j = V6c\_ ( j - 1 ) + V 6 S + V6S\_ ( j - 1 ) = ( V6\_ 0 + V 6 S ) + \sum V6S\_k ,$$

where “ΣV6S_k” is the total sum of the shift values “V6S_0”, “V6S_1”, . . . , and “V6S_(j−1)”.

The minus read level V6m and the offset value that are related to the threshold voltage distribution S6 in the minus reading have the following relationship.

$$V6m\_j = V6c\_j - 10 DAC$$

The plus read level V6p and the offset value that are related to the threshold voltage distribution S6 in the plus reading have the following relationship.

$$V6p\_j = V6c\_j + 10 DAC$$

Regarding each of the threshold voltage distributions S2, S4, and S6 in the middle page, the read level is set using the above formulas (calculation processing). Standard reading, minus reading, and plus reading are executed using the set read level.

(b-3-1) <Determination Processing Regarding Threshold Voltage Distribution S2>

In the present embodiment, the determination of the magnitude of the threshold voltage is executed from the determination using a low read level. In the reading of the middle page, in order to determine the state related to the threshold voltage distribution S2, the determination of the threshold voltage of the memory cell MC related to the threshold voltage distribution S2 is executed in the order of the minus read level V2m, the standard read level V2c, and the plus read level V2p.

Each of the read levels V2m, V2c, and V2p is sequentially applied to the selected word line WL. The voltage VREAD is applied to the non-selected word line WL. The bit line BL is charged.

Between the two adjacent states, the memory cell MC on the left (lower potential side) from the read level is determined as “0”, and the memory cell MC on the right (higher potential side) is determined as “1”. By the application of the read levels V2 (V2c, V2m, and V2p) to the selected word line, it is determined whether the threshold voltage of the memory cell MC is equal to or higher than the read level V2 or lower than the read level V2.

As illustrated in FIG. 8, the determination result data D2m related to the minus read level V2m (for example, the minus read level V2m_1) is stored in the data latch EDL. The determination result data D2c related to the standard read level V2c (for example, the read level V2c_1) is stored in the data latch ADL. The determination result data D2p related to the plus read level V2p (for example, the plus read level V2p_1) is stored in the data latch FDL.

Here, the data latch DL that stores the determination result data Dic related to the standard read level Vic is not overwritten with other data until the automatic adjustment read operation is ended. That is, the data latch ADL stores the determination result data D2c until the automatic adjustment read operation is ended.

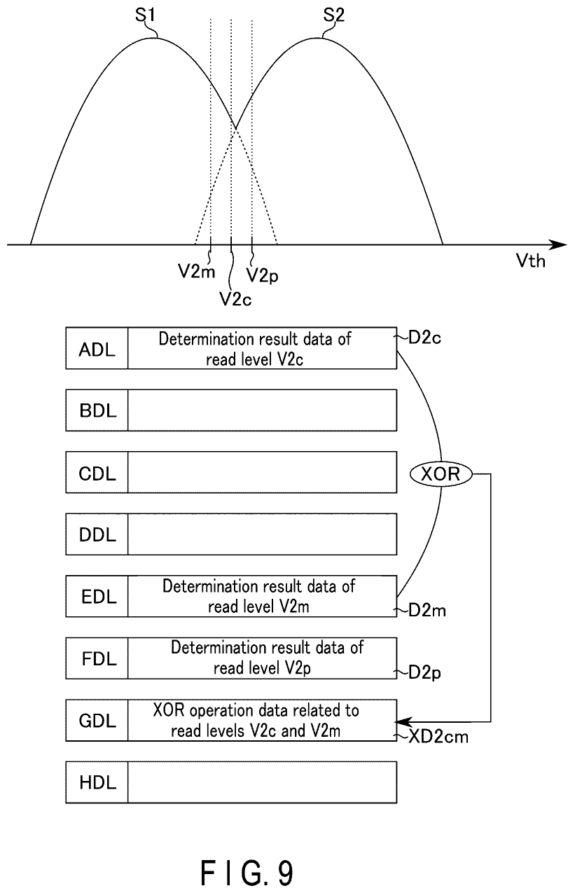

As illustrated in FIG. 9, the error bit detection circuit 50 executes an XOR operation for each memory cell MC on the determination result data D2m in the data latch EDL and the determination result data D2c in the data latch ADL. Data XD2cm indicating the result of the XOR operation on the determination result data D2c of the standard read level V2c and the determination result data D2m of the minus read level V2m (hereinafter referred to as XOR operation data) is stored in the data latch GDL.

The XOR operation data XD2cm is data for verifying whether the determination result of the threshold voltage of the memory cell MC by the standard read level V2c matches or does not match the determination result of the threshold voltage of the memory cell MC by the minus read level V2m. The XOR operation data XD2cm is hereinafter also referred to as verification data.

Here, in a case where the values read from the same memory cell MC match between the determination result data D2c of the data latch ADL and the determination result data D2m of the data latch EDL, the value of the XOR operation data XD2cm of the data latch GDL is “0”. On the other hand, in a case where the values read from the same memory cell MC does not match between the determination result data D2c of the data latch ADL and the determination result data D2m of the data latch EDL, the value of the XOR operation data XD2cm of the data latch GDL is “1”.

In a case where the values of all the bits of the determination result data D2c of the data latch ADL and the determination result data D2m of the data latch EDL match, all the values of the XOR operation data XDcm in the data latch GDL become zero (“all 0”).

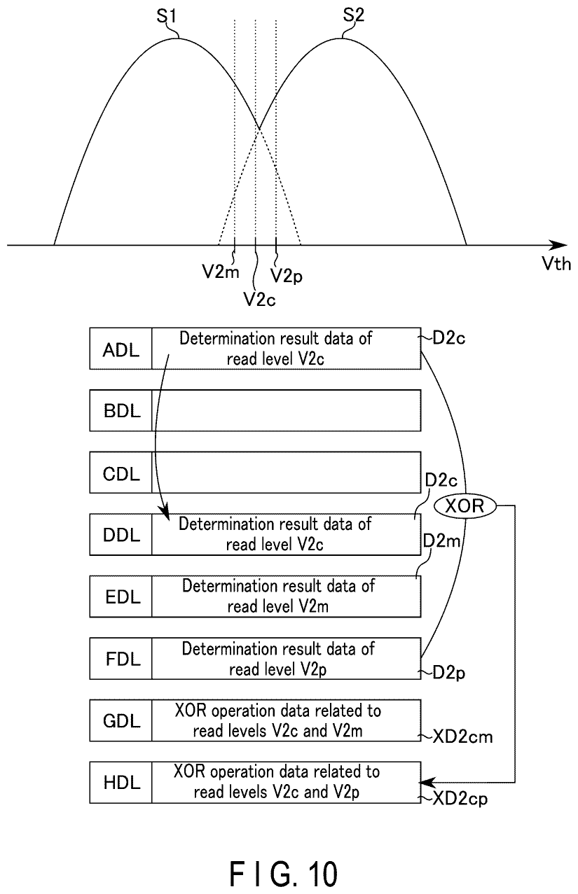

As illustrated in FIG. 10, the error bit detection circuit 50 executes the XOR operation on the determination result data D2p in the data latch FDL and the determination result data D2c in the data latch ADL for each corresponding memory cell. The XOR operation data XD2cp indicating the result of the XOR operation on the determination result data D2c of the standard read level V2c and the determination result data D2p of the plus read level V2p is stored in the data latch HDL.

The XOR operation data XD2cm is data for verifying whether the determination result of the threshold voltage of the memory cell MC by the standard read level V2c matches or does not match the determination result of the threshold voltage of the memory cell MC by the plus read level V2p.

Here, in a case where the values read from the same memory cell MC match between the determination result data D2c of the data latch ADL and the determination result data D2p of the data latch FDL, the value of the XOR operation data XD2cp of the data latch HDL is “0”. On the other hand, in a case where the values read from the same memory cell MC does not match between the determination result data D2c of the data latch ADL and the determination result data D2p of the data latch FDL, the value of the XOR operation data XD2cp of the data latch HDL is “1”.

For example, in a case where the values of all the bits of the determination result data D2c of the data latch ADL and the determination result data D2p of the data latch FDL match, all the values of the XOR operation data XDcp in the data latch HDL become zero (“all 0”).

The determination result data D2c of the data latch ADL is transferred to, for example, the data latch DDL.

(b-3-2) <Determination Processing Regarding Threshold Voltage Distribution S4>

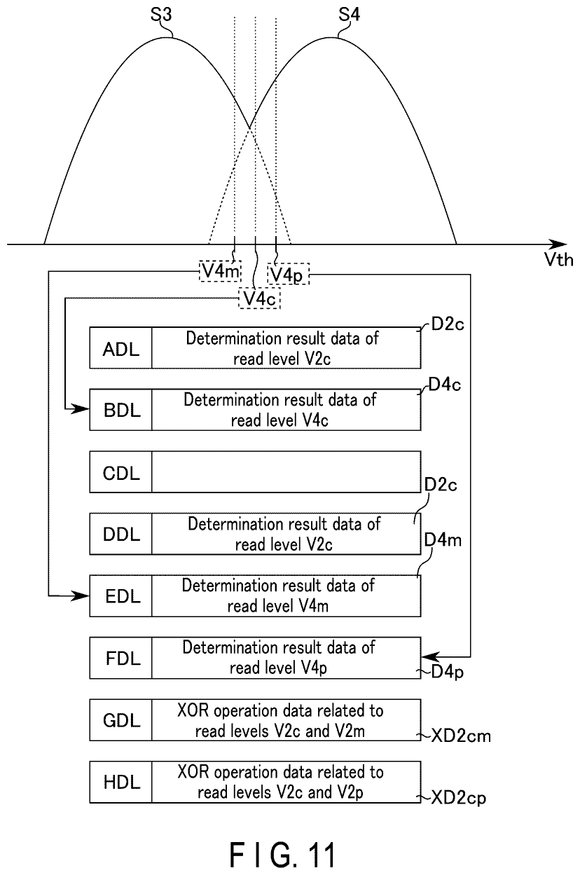

As illustrated in FIG. 11, after the determination of the threshold voltage of the memory cell MC by the read levels V2 (V2c, V2m, and V2p), the determination of the threshold voltage of the memory cell MC related to the threshold voltage distribution S4 is executed. The determination of the threshold voltage of the memory cell MC related to the threshold voltage distribution S4 is executed in the order of the minus read level V4m, the standard read level V4c, and the plus read level V4p.

Each of the read levels V4m, V4c, and V4p is sequentially applied to the selected word line WL. The voltage VREAD is applied to the non-selected word line WL. The bit line BL is charged.

By the application of the read levels V4 (V4c, V4m, and V4p), it is determined whether the threshold voltage of the memory cell MC is equal to or higher than the threshold voltage distribution S4 or lower than the threshold voltage distribution S4.

The determination result data D4m of the minus read level V4m (for example, minus read level V4m_1) is stored in the data latch EDL. The determination result data D4c of the standard read level V4c (for example, read level V4c_1) is stored in the data latch BDL. The determination result data D4p of the plus read level V4p (for example, plus read level V4p_1) is stored in the data latch FDL.

As described above, the determination result data Dim using the minus read level is stored in the data latch EDL. In addition, the determination result Dip using the plus read level is stored in the data latch FDL. The data in the data latches EDL and FDL is rewritten every time the threshold voltage of the memory cell MC of each threshold voltage distribution is determined.

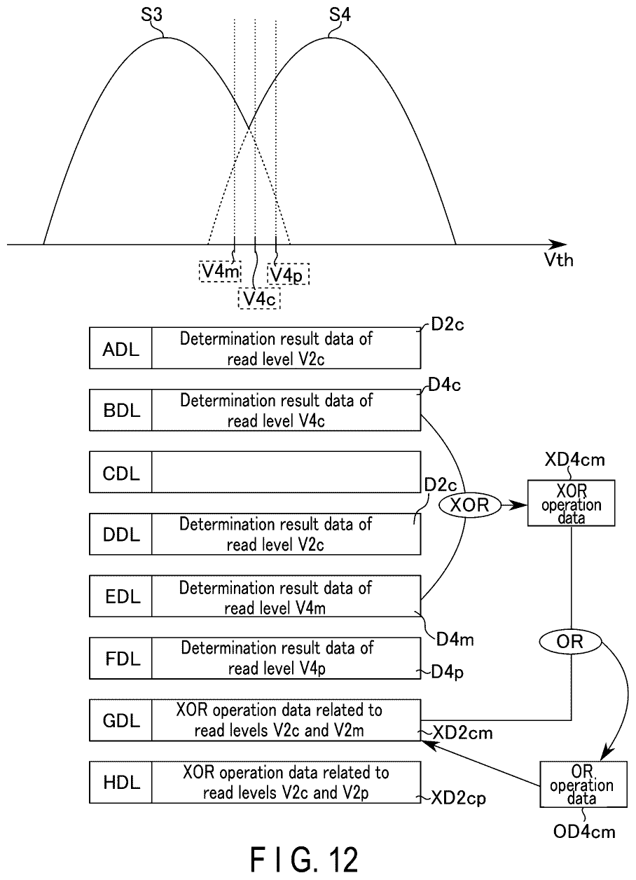

As illustrated in FIG. 12, the error bit detection circuit 50 executes an XOR operation for each memory cell MC on the determination result data D4m in the data latch EDL and the determination result data D4c in the data latch BDL. Accordingly, the XOR operation data XD4cm indicating the result of the XOR operation on the determination result data D4c of the read level V4c and the determination result data D4m of the read level V4m is generated.

The error bit detection circuit 50 executes an OR operation on the XOR operation data XD4cm, and the XOR operation data XD2cm in the data latch GDL. Accordingly, operation data indicating a result of the OR operation (hereinafter referred to as OR operation data) OD4cm is generated.

The OR operation data OD4cm is stored in the data latch GDL. The XOR operation data XD2cm having been stored in the data latch GDL is rewritten to OR operation data OD4cm. As described above, the data in the data latch GDL is rewritten by the OR operation data ODicm of pieces of the XOR operation data XDicm with different threshold voltages.

The OR operation data OD4cm is data (hereinafter also referred to as verification data) for verifying the cumulative number of matches/mismatches between the determination result of the threshold voltages of the memory cell MC by the standard read levels V2c and V4c and the determination result of the threshold voltages of the memory cell MC by the minus read levels V2m and V4m.

Regarding the OR operation data OD4cm based on the determination results of the threshold voltage distribution S2 and the threshold voltage distribution S4, in a case where the determination result at the minus read level V2m is equal to the determination result at the standard read level V2c and the determination result at the minus read level V4m is equal to the determination result at the standard read level V4c, the value of the OR operation data OD4cm in the data latch GDL is “0”. On the other hand, in a case where the determination result at the minus read level V2m is different from the determination result at the standard read level V2c or the determination result at the minus read level V4m is different from the determination result at the standard read level V4c, the value of the OR operation data OD4cm in the data latch GDL is “1”.

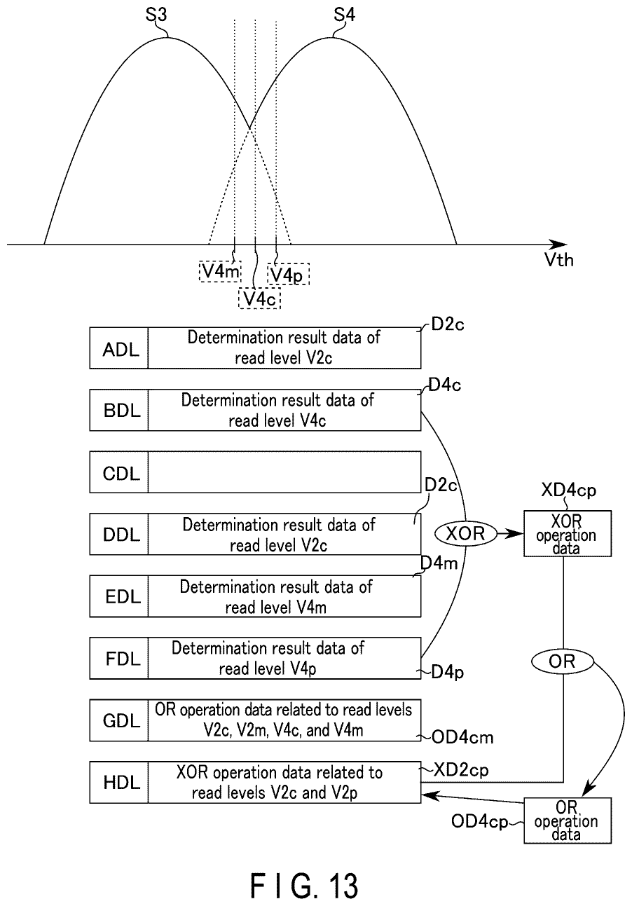

As illustrated in FIG. 13, the error bit detection circuit 50 executes the XOR operation on the determination result data D4p in the data latch FDL and the determination result data D4c in the data latch BDL for each corresponding memory cell MC. Accordingly, the XOR operation data XD4cp indicating the result of the XOR operation on the determination result data D4c of the standard read level V4c and the determination result data D4p of the plus read level V4p is generated.

The error bit detection circuit 50 executes an OR operation on the XOR operation data XD4cp, and the XOR operation data XD2cp in the data latch HDL. Accordingly, OR operation data OD4cp indicating a result of the OR operation is generated.

The OR operation data OD4cp is stored in the data latch HDL. The data in the data latch HDL is rewritten by the OR operation data OD4cp.

The OR operation data OD4cp is data for verifying the cumulative number of matches/mismatches between the determination result of the threshold voltages of the memory cell MC by the standard read levels V2c and V4c and the determination result of the threshold voltages of the memory cell MC by the plus read levels V2p and V4p.

Regarding the OR operation data OD4cp based on the determination results of the threshold voltage distribution S2 and the threshold voltage distribution S4, in a case where the determination result at the plus read level V2p is equal to the determination result at the standard read level V2c and the determination result at the plus read level V4p is equal to the determination result at the standard read level V4c, the value of the OR operation data OD4cp in the data latch HDL is “0”. On the other hand, in a case where the determination result at the plus read level V2p is different from the determination result at the standard read level V2c or the determination result at the plus read level V4p is different from the determination result at the standard read level V4c, the value of the OR operation data OD4cp in the data latch HDL is “1”.

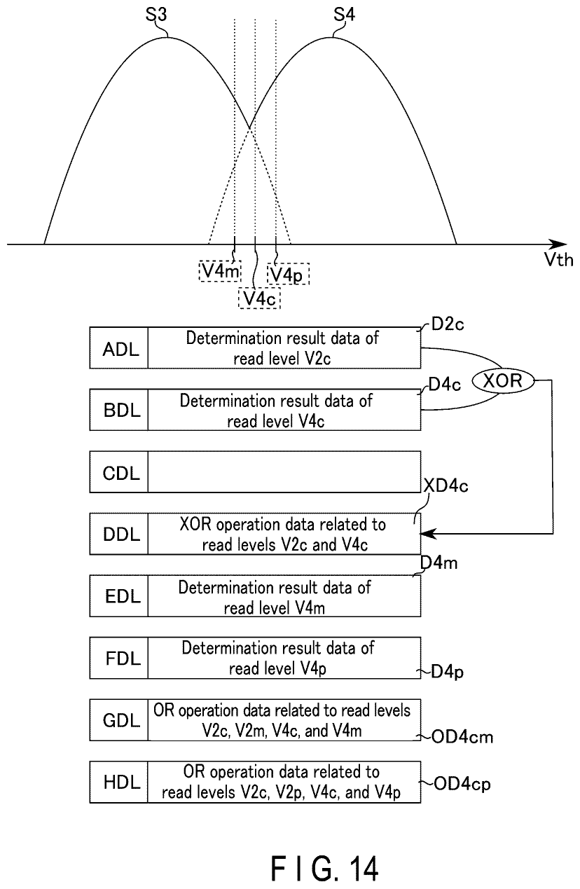

As illustrated in FIG. 14, an XOR operation on the determination result data D4c of the data latch BDL and the determination result data D2c of the data latch ADL is executed. The XOR operation data XD4c indicating the result of the XOR operation is stored in the data latch DDL.

It should be noted that instead of the determination result data D2c in the data latch ADL, the XOR operation data XD4c may be generated by the XOR operation on the determination result data D2c in the data latch DDL before rewriting and the determination result data D4c in the data latch BDL.

(b-3-3) <Determination Processing Regarding Threshold Voltage Distribution S6>

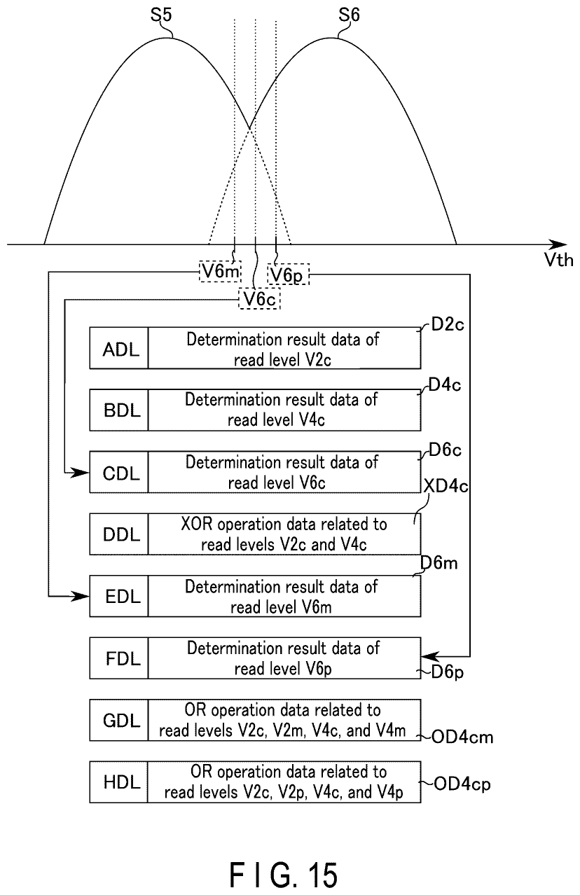

As illustrated in FIG. 15, after the determination based on the read levels V4(V4c, V4m, and V4p), the determination of the threshold voltage of the memory cell MC related to the threshold voltage distribution S6 is executed. The determination of the threshold voltage of the memory cell MC related to the threshold voltage distribution S6 is executed in the order of the minus read level V6m, the standard read level V6c, and the plus read level V6p.

Each of the read levels V6m, V6c, and V6p is sequentially applied to the selected word line WL. The voltage VREAD is applied to the non-selected word line WL. The bit line BL is charged.

By the application of each of the read levels V6 (V6c, V6m, and V6p), it is determined whether the threshold voltage of the memory cell MC is equal to or higher than the threshold voltage distribution S6 or lower than the threshold voltage distribution S6.

The determination result data D6m of the minus read level V6m (for example, read level V6m_1) is stored in the data latch EDL. The determination result data D6c of the standard read level V6c (for example, read level V6c_1) is stored in the data latch CDL. The determination result data D6p of the plus read level V6p (for example, read level V6p_1) is stored in the data latch FDL.

As described above, the data in the data latches EDL and FDL is rewritten from the determination result of the threshold voltage of the memory cell MC of the threshold voltage distribution S4 to the determination result of the threshold voltage of the memory cell MC of the threshold voltage distribution S6.

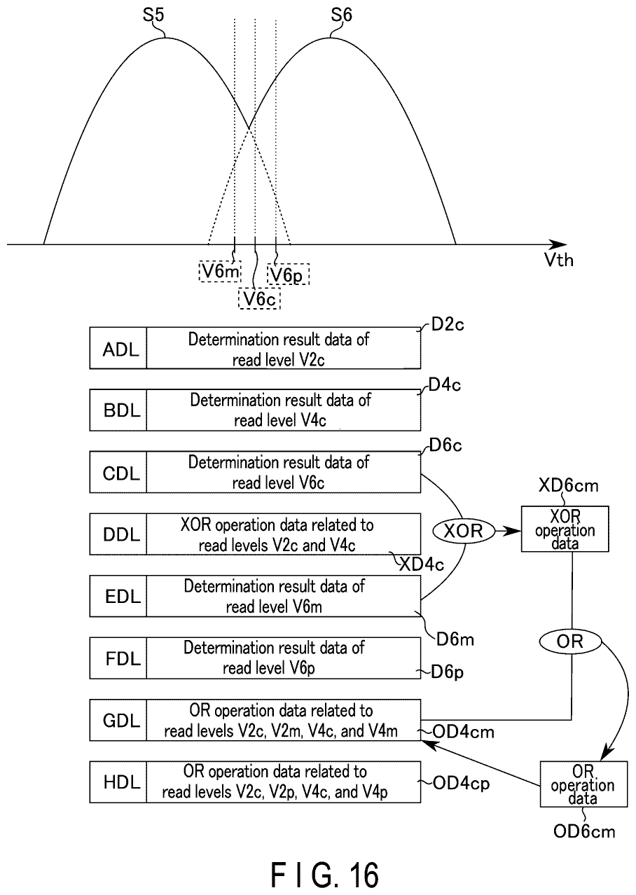

As illustrated in FIG. 16, the error bit detection circuit 50 executes an XOR operation for each corresponding memory cell MC on the determination result data D6m in the data latch EDL and the determination result data D6c in the data latch CDL. Accordingly, the XOR operation data XD6cm indicating the result of the XOR operation on the determination result data D6c of the standard read level V6c and the determination result data D6m of the minus read level V6m is generated.

The error bit detection circuit 50 executes an OR operation on the generated XOR operation data XD6cm, and the OR operation data OD4cm in the data latch GDL. Accordingly, OR operation data OD6cm is generated.

The OR operation data OD6cm is stored in the data latch GDL. Accordingly, the OR operation data OD4cm having been stored in the data latch GDL is rewritten to OR operation data OD6cm.

The OR operation data OD6cm is data for verifying the cumulative number of matches/mismatches between the determination result of the threshold voltages of the memory cell MC by the standard read levels V2c, V4c, and V6c and the determination result of the threshold voltages of the memory cell MC by the minus read levels V2m, V4m, and V6m.

Regarding the OR operation data OD6cm based on the determination results of the threshold voltage distribution S2, the threshold voltage distribution S4, and the threshold voltage distribution S6, in a case where the determination result at the minus read level V2m is equal to the determination result at the standard read level V2c, the determination result at the minus read level V4m is equal to the determination result at the standard read level V4c, and the determination result at the minus read level V6m is equal to the determination result at the standard read level V6c, the value of the OR operation data OD6cm in the data latch GDL is “0”. On the other hand, in a case where the determination result at the minus read level V2m is different from the determination result at the standard read level V2c, the determination result at the minus read level V4m is different from the determination result at the standard read level V4c, or the determination result at the minus read level V6m is different from the determination result at the standard read level V6c, the value of the OR operation data OD6cm in the data latch GDL is “1”.

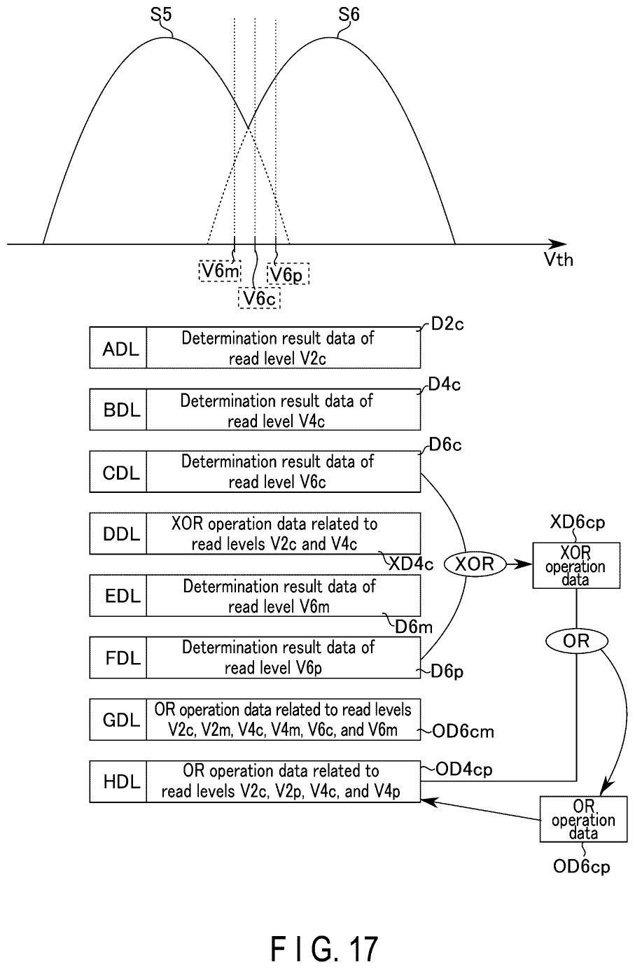

As illustrated in FIG. 17, the error bit detection circuit 50 executes an XOR operation for each corresponding memory cell MC on the determination result data D6p in the data latch FDL and the determination result data D6c in the data latch CDL. Accordingly, the XOR operation data XD6cp indicating the result of the XOR operation on the determination result data D6c of the standard read level V6c and the determination result data D6p of the plus read level V6p is generated.

The error bit detection circuit 50 executes an OR operation on the generated XOR operation data XD6cp, and the OR operation data OD4cp in the data latch HDL. Accordingly, OR operation data OD6cp is generated.

The OR operation data OD6cp is stored in the data latch HDL. The OR operation data OD4cp having been stored in the data latch HDL is rewritten to OR operation data OD6cp.

The OR operation data OD6cp is data indicating the cumulative number of matches/mismatches between the determination result of the threshold voltages of the memory cell MC by the standard read levels V2c, V4c, and V6c and the determination result of the threshold voltages of the memory cell MC by the plus read levels V2p, V4p, and V6p.

Regarding the OR operation data OD6cp based on the determination results of the threshold voltage distribution S2, the threshold voltage distribution S4, and the threshold voltage distribution S6, in a case where the determination result at the plus read level V2p is equal to the determination result at the standard read level V2c, the determination result at the plus read level V4p is equal to the determination result at the standard read level V4c, and the determination result at the plus read level V6p is equal to the determination result at the standard read level V6c, the value of the OR operation data OD6cp in the data latch HDL is “0”. On the other hand, in a case where the determination result at the plus read level V2p is different from the determination result at the standard read level V2c, the determination result at the plus read level V4p is different from the determination result at the standard read level V4c, or the determination result at the plus read level V6p is different from the determination result at the standard read level V6c, the value of the OR operation data OD6cp in the data latch HDL is “1”.

As described above, based on the determination result of the threshold voltage of the memory cell MC based on the standard read level and the offset read level, matches and mismatches in the determination results at each read level are detected.

(b-4) <Sp22>

The NAND memory 30 generates read data based on the determination result of each read level related to the selected page.

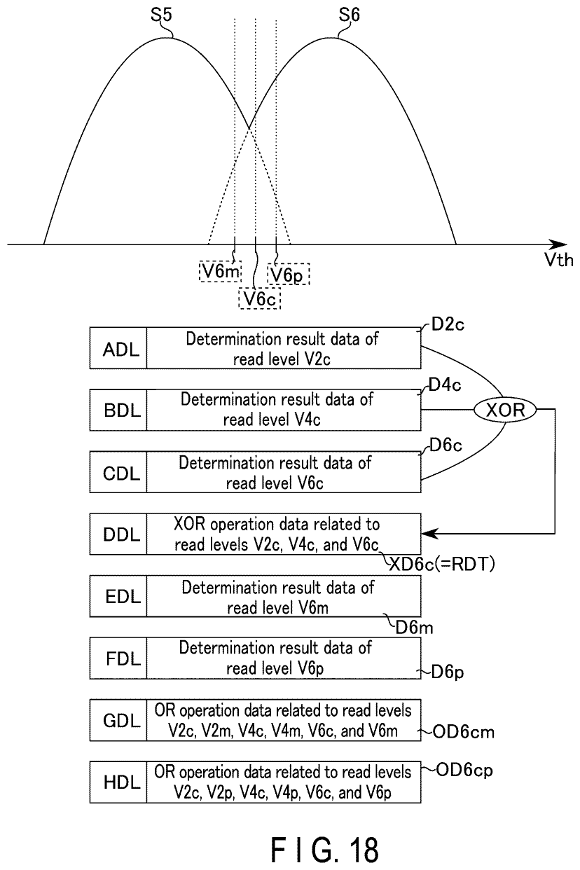

As illustrated in FIG. 18, an XOR operation on the determination result data D6c of the data latch CDL, the determination result data D4c of the data latch BDL, and the determination result data D2c of the data latch ADL is executed. The XOR operation data XD6c indicating the result of the XOR operation is stored in the data latch DDL.

It should be noted that the data latch DDL stores the XOR operation data XD4c of the determination result data D2c related to the read level V2c and the determination result data D4c related to the read level V4c before the writing of the data XD6c. Therefore, instead of the data D2c and D4c of the data latches ADL and BDL, the data XD6c may be generated by an XOR operation on the data XD4c of the data latch DDL and the data D6c of the data latch CDL.

The determination result data D2c, D4c, and D6c of the data latches ADL, BDL, and CDL are determination result data related to the three standard read levels V2c, V4c, and V6c of the middle page.

Therefore, the standard read data Dc is generated by the XOR operation on the determination result data D2c, D4c, and D6c of the data latches ADL, BDL, and CDL. That is, the read data RDT of the middle page is generated by the XOR operation on the determination result data D2c, D4c, and D6c of the standard read levels V2c, V4c, and V6c.

As described above, the read data RDT is acquired by the automatic adjustment read operation of the memory system 1 of the present embodiment.

In addition, after the generation of the read data RDT, the following information (data) is stored in each of the data latches ADL, BDL, . . . , and GDL.

The data latch ADL stores the determination result data D2c by the read level V2c for generating the read data RDT of the middle page.

The data latch BDL stores the determination result data D4c by the read level V4c for generating the read data RDT of the middle page.

The data latch CDL stores the determination result data D6c by the read level V6c for generating the read data RDT of the middle page.

The data latch DDL stores the read data RDT of the middle page.

The data latch EDL stores the determination result data (temporary data) D6m by the minus read level V6m. Here, the temporary data is data that may be rewritten to other data before the automatic adjustment read operation is finished.

The data latch FDL stores the determination result data (temporary data) D6p by the plus read level V6p.

The data latch GDL stores data OD6cm for verifying matches/mismatches between the read data Dc by the standard read level Vc and the read data Dm by the minus read level Vm.

The data latch HDL stores data OD6cp for verifying matches/mismatches between the read data Dc by the standard read level Vc and the read data Dp by the plus read level Vp.

The data OD6cm in the data latch GDL is data obtained by cumulating data obtained by the XOR operation for each memory cell MC on the determination result data D2c, D4c, and D6c by the standard read levels V2c, V4c, and V6c and the determination result data D2m, D4m, and D6m by the minus read levels V2m, V4m, and V6m by the OR operation for each memory cell MC. That is, the data OD6cm in the data latch GDL is data indicating whether the read data of the standard read level and the read data of the minus read level match in the determination results of all the read levels or there is a determination result of the read level that does not match.

The data OD6cp in the data latch HDL is data obtained by cumulating data obtained by the XOR operation for each memory cell MC on the determination result data D2c, D4c, and D6c by the standard read levels V2c, V4c, and V6c and the determination result data D2p, D4p, and D6p by the plus read levels V2p, V4p, and V6p by the OR operation for each memory cell MC. That is, the data OD6cp in the data latch HDL is data indicating whether the read data of the standard read level and the read data of the plus read level match in the determination results of all the read levels or there is even one determination result of the read level that does not match.

(b-5) <Sp11, Sp23, and Sp12>

The memory controller 10 commands the NAND memory 30 to output the read data RDT by the command set CS1.

The error bit detection circuit 50 checks whether the read level is an appropriate value (for example, an optimum value) based on the data in the data latch DL.

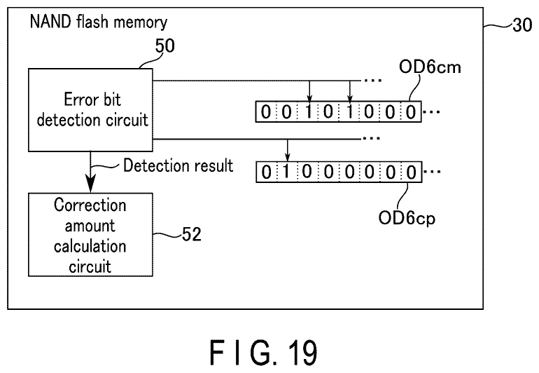

FIG. 19 is a schematic diagram for illustrating processing for checking the appropriateness of the read level by the error bit detection circuit 50 in the memory system of the present embodiment.

For example, as illustrated in FIG. 19, the error bit detection circuit 50 counts the number of “1”s included in the data OD6cm of the data latch GDL and the number of “1”s included in the data OD6cp of the data latch HDL. That is, the error bit detection circuit 50 counts the number of mismatched bits between the determination result data of the standard read level and the determination result data of the minus read level and the number of mismatched bits between the determination result data of the standard read level and the determination result data of the plus read level.

For example, the error bit detection circuit 50 counts the number of mismatched bits in parallel with outputting the read data RDT from the input/output circuit 32 to the memory controller 10.

As described with reference to (a) of FIG. 5, the NAND memory 30 outputs the read data RDT to the memory controller 10 via the input/output circuit 32 by 8 bits at a predetermined timing with the designated address ADD as a head according to the output commands (commands of “05h” and “EOh”) of the command set CS1.

The memory controller 10 receives read data.

In the present embodiment, the NAND memory 30 independently counts the number of bits of “1” of each of the OR operation data (verification data) OD6cm in the data latch GDL and the OR operation data (verification data) OD6cp in the data latch HDL for each output cycle of the read data RDT.

Here, the data in which the number of mismatched bits (“1”s) is counted is data having a data size in IO units and corresponding to data including an 8-bit signal DQ [7:0] to be simultaneously output.

However, in a case where it is difficult to collectively count data for eight bits due to high-speed data output, the bit-by-bit calculation corresponding to the signal DQ [7:0] may be performed by cumulating the eight bits of the data OD6cm from the data latch GDL and the eight bits of the data OD6cp from the data latch HDL in parallel.

When the output of the read data RDT is completed, the number of “1”s in the OR operation data OD6cm of the data latch GDL and the OR operation data OD6cp of the data latch HDL corresponding to the output data length (data amount) is obtained.

In a case where the shape of the threshold voltage distribution of each state corresponding to the data in the NAND memory 30 is regarded as bilaterally symmetrical, the NAND memory 30 causes the error bit detection circuit 50 to compare the number of “1”s of the verification data OD6cm in the data latch GDL with the number of “1”s of the verification data OD6cp in the data latch HDL in each bit of the verification data OD6cm and OD6cp corresponding to the data range output from the input/output circuit 32 of the NAND memory 30.

The NAND memory 30 causes the correction amount calculation circuit 52 to calculate the dynamic shift value based on the measurement results of the verification data OD6cm and OD6cp so that the read level is shifted to the side of the read level corresponding to the verification data in which the number of “1”s of the verification data OD6cm and OD6cp is smaller. The voltage value of the read level is set by the calculated dynamic shift value. That is, the NAND memory 30 sets the voltage value of the read level so that the read level is shifted to the side of the read level corresponding to the verification data in which the number of matches with the standard read data is larger.

As a result, the memory system 1 of the present embodiment reduces the number of error bits included in the read data by the read operation performed after the correction of the read level.

The correction amount calculation circuit 52 calculates the dynamic shift value of the read level (standard read level) based on the number of “1”s of the verification data OD6cm in the data latch GDL, and the number of “1”s of the verification data OD6cp in the data latch HDL in order to correct the voltage value of the read level.

For example, the calculation of the dynamic shift value of the read level is calculated as follows.

Comparison between the number of “1”s included in the verification data OD6cm in the data latch GDL (hereinafter, denoted as “g”) and the number of “1”s included in the verification data OD6cp in the data latch HDL (hereinafter, denoted as “h”) and calculation of the dynamic shift value of the read level are executed by acquisition of a difference or acquisition of a ratio.

Hereinafter, the value indicated by “Delta” corresponds to the value of the comparison result and the dynamic shift value of the reference of the read level.

The comparison based on acquisition of the difference and the calculation of the dynamic shift value are expressed by the following Formula (F0).

$$Delta = g - h \qquad ( F0 )$$

The comparison based on the acquisition of the ratio and the calculation of the dynamic shift value are expressed by the following Formula (F1a).

$$Delta = ( g + 1 ) / ( h + 1 ) \qquad ( F1a )$$

It should be noted that Delta based on the acquisition of the ratio can be expressed by the following Formula (Fib).

$$Delta = log ( g + 1 ) / ( h + 1 ) \qquad ( F1b )$$

In a case where the dynamic shift value Delta is calculated based on the ratio, the addition of 1 to each of “g” and “h” is to prevent “g” from being divided by 0 in a case where “h” is 0.

By obtaining the logarithmic ratio, comparison, and calculation of the dynamic shift value may be executed. In a case where the comparison of the error bits and the calculation of the dynamic shift value are executed by the logarithmic ratio, the dynamic shift value Delta is calculated as in the following formula (F2).

$$Delta = log \{ ( g + 1 ) / ( h + 1 ) \} = log ( g + 1 ) - log ( h + 1 ) , \qquad ( F2 )$$

where the addition of 1 to each of “g” and “h” is to prevent “log 0”.

In addition, by setting the base of the logarithm in “log (g+1)/(h+1)” to “2”, in a case where “g” or “h” is indicated by a binary number, the integer part of log is the number of digits of “g+1” and “h+1”. Therefore, the dynamic shift value can be approximated by the difference in the number of digits of the binary representation of “g+1” and “h+1”. For example, in a case where represented in binary numbers, the dynamic shift value can be approximated by a difference between the positions of the highest number of digits in “1”s (leftmost bit position among numerical values “1” represented by binary number).

It should be noted that the comparison of the error bits and the calculation of the dynamic shift value may be calculated by a bilinear expression using “g” and “h” as variables. A bilinear expression for calculating the dynamic shift value Delta is expressed by the following Formula (F3).

$$Delta = Cg \times g - Ch \times h + Cf , \qquad ( F3 )$$

where “Cg” is an integer coefficient for “g”, “Ch” is an integer coefficient for “h”, and “Cf” is an integer constant. For example, in a case where Cg=1, Ch=1, and Cf=0, Formula (F3) matches Formula (F0) for obtaining a dynamic shift value by a difference between “g” and “h”.

In the dynamic shift value Delta, in the above-described formulas (F0) and (F1a), in a case where “g” is equal to “h” (in a case where Delta=0), it is assumed that there is no correction of the read level.

In a case where “g” is greater than “h”, the voltage value of the read level is shifted in the direction of the high voltage by a dynamic shift value Delta of a predetermined voltage value (for example, about 1 DAC). In a case where “g” is smaller than “h”, the read level is shifted in the direction of the low voltage by a dynamic shift value Delta of a predetermined voltage value (for example, about 1 DAC).

It should be noted that the dynamic shift value Delta may be corrected by the number of DACs proportional to the dynamic shift value Delta, or may be corrected by the number of DACs proportional to the power of 1/n (for example, to the power of ½) of the absolute value of the dynamic shift value Delta.

In a case where the dynamic shift value Delta is determined by the above-described Formula (F2), in a case where the dynamic shift value Delta is greater than 0, the read level is shifted to the higher voltage side by the number of DACs of an integer value of the absolute value of the dynamic shift value Delta (|Delta|). In a case where the dynamic shift value Delta is smaller than 0, the read level is shifted to the lower voltage side by the number of DACs of an integer value of the absolute value of the dynamic shift value Delta (|Delta|).

It should be noted that, as in the example of the bilinear expression of the Formula (F3), the read level may be corrected by a constant multiple of the absolute value |Delta| of the dynamic shift value Delta.

By the dynamic shift value Delta determined by any one of the above-described formulas (F0), (F1a), (Fib), (F2), and (F3), in an access to the same NAND memory 30, a read level including the calculated dynamic shift value is used during the read operation on a page (in this example, the middle page) of the same address next time.

For example, in a case where the threshold voltage distribution changes due to data retention, the higher the threshold voltage distribution, the larger the voltage movement amount tends to be.

In a case where the read levels V2 (V2c), V4 (V4c), and V6 (V6c) in the middle page are corrected, for example, dynamic shift values of the read levels V2, V4, and V6 respectively associated with the threshold voltage distributions S2, S4, and S6 are determined as follows.
Dynamic shift value of read level V2 with respect to threshold voltage distribution S2: 1/3×Delta
where the dynamic shift value is an integer part of 1/3×Delta
Dynamic shift value of read level V4 with respect to threshold voltage distribution S4: 1/2 Delta
where the dynamic shift value is an integer part of 1/2×Delta
Dynamic shift value of read level V6 with respect to threshold voltage distribution S6: 7/5 Delta
where the dynamic shift value is an integer part of 7/5×Delta

In a case where the dynamic shift value acquired in the logarithmic ratio of “g” and “h” is applied to the next read operation, the dynamic shift values of the read levels V2, V4, and V6 are as follows,
where the initial value of the cumulative shift value V2S of the read level V2 is assumed to be “+1”. The initial value of the shift value V4S of the read level V4 is assumed to be “−2”. The shift value V6S of the read level V6 is assumed to be “−5”.

It is assumed that in the read operation for a certain middle page, “g” is 5 and “h” is 132 in the first read operation, and “g” is 20 and “h” is 4 in the second read operation.

In the first read operation, the standard read levels V2c_1, V4c_1, and V6c_1 are set as follows.
Read level V2c related to threshold voltage distribution S2: V2c 1=V2_0+V2S
Read level V4c related to threshold voltage distribution S4: V4c 1=V4_0+V4S
Read level V6c related to threshold voltage distribution S6: V6c 1=V6_0+V6S

The read operation is executed using the read level set in this manner.

Based on “g=5” and “h=132” assumed as described above, the dynamic shift value is determined by the logarithmic ratio.

$$\begin{matrix}Delta = {log}_{2} \{ ( g + 1 ) / ( h + 1 ) \} \\ = {log}_{2} ( 5 + 1 ) - {log}_{2} ( 132 + 1 ) \\ = {log}_{2} ( 6 ) - {log}_{2} ( 33 ) \\ = {log}_{2} ( 4 + 2 ) - {log}_{2} ( 128 + 5 )\end{matrix} \qquad ( F 4 )$$

In Formula (F4), considering only the integer part, “log₂ (4)=2” and “log₂ (128)=7” are obtained. Therefore, the integer part of Formula (F4) is expressed by the following Formula (F5).

$$Integer part of Delta : 2 - 7 = - 5 \qquad ( F 5 )$$

It should be noted that in a case where “6” in a decimal number is represented as a binary number, it is “00000110”. Let the least significant bit (LSB) be the bit [0] (first digit), then the position of the leftmost “1” in “00000110” is the bit [2] (third digit). In addition, in a case where “133” in a decimal number is represented as a binary number, it is “10000101”. The position of the leftmost “1” in “10000101” is the bit [7] (eighth digit).

In the example of Formula (F5), “g” corresponding to the read level being offset to the lower voltage side (minus read level) is smaller than “h” corresponding to the read level being offset to the higher voltage side (plus read level). That is, the difference (the number of mismatches) between the standard read data and the plus read data is larger than the difference (the number of mismatches) between the standard read data and the minus read data. Therefore, in the next read operation for the same address, a decrease in the number of error bits is expected by moving the read level to the lower voltage side.

Using the dynamic shift value Delta obtained by Formula (F5), each of the corrected read levels V2c_2, V4c_2, and V6c_2 for the second read operation is determined as follows.

The read level V2c_2 in the second read operation is calculated as in the following Formula (F6a).

$$\begin{matrix}V 2 c\_ 2 = V 2 c\_ 1 + 1 / 2 \times Delta \\ = V 2 c\_ 1 + 1 / 2 \times ( - 5 ) \\ = V 2 c\_ 1 - 5 / 2\end{matrix} , \qquad ( F 6 a )$$

where considering only the integer part of Formula (F6a), the read level V2c to be corrected is expressed by the following Formula (F6b).

$$\begin{matrix}V 2 c\_ 2 = V 2 \_ 1 - 2 \\ = V 2 \_ 0 + V 2 S - 2 \\ = V 2 \_ 0 + 1 - 2 \\ = V 2 \_ 0 - 1\end{matrix} \qquad ( F 6 b )$$

The read level V4c_2 in the second read operation is calculated as in the following Formula (F7a).

$$\begin{matrix}V 4 c\_ 2 = V 4 c\_ 1 + 1 / 3 \times Delta \\ = V 4 c\_ 1 + 1 / 3 \times ( - 5 ) \\ = V 4 c\_ 1 - 5 / 3\end{matrix} , \qquad ( F 7 a )$$

where considering only the integer part of Formula (F7a), the read level V4c to be corrected is expressed by the following Formula (F7b).

$$\begin{matrix}V 4 c\_ 2 = V 4 c \_ 1 - 1 \\ = V 4 \_ 0 + V 4 S - 1 \\ = V 4 \_ 0 - 2 - 1 \\ = V 4 \_ 0 - 3\end{matrix} \qquad ( F 7 b )$$

The read level V6c_2 in the second read operation is calculated as in the following Formula (F8a).

$$\begin{matrix}V 6 c\_ 2 = V 6 c\_ 1 + 7 / 5 \times Delta \\ = V 6 c\_ 1 + 7 / 5 \times ( - 5 ) \\ = V 6 c\_ 1 - 35 / 5\end{matrix} , \qquad ( F 8 a )$$

where considering only the integer part of Formula (F8a), the read level V6c to be corrected is expressed by the following Formula (F8b).

$$\begin{matrix}V 6 c\_ 2 = V 6 c \_ 1 - 7 \\ = V 6 \_ 0 - 5 - 7 \\ = V 6 \_ 0 - 12\end{matrix} \qquad ( F 8 b )$$

In a case where the second read operation is executed on the same middle page, the standard reading (and the offset reading) is executed using the standard read levels V2c_2, V4c_2, and V6c_2 corrected based on the above Formulas (F6b), (F7b), and (F8b) as a reference.

The read operation according to the next read command (for example, the second read operation) is executed using the read level obtained from the default read level and the cumulative shift values (V2S′, V4S′, and V6S′) as follows. For example, the cumulative shift values V2S′, V4S′, and V6S′ include a static shift value, a designated shift value set by the memory controller 10, and a dynamic shift value acquired by the automatic adjustment read operation of the NAND memory 30.
Read level V2c related to threshold voltage distribution S2: V2c 2=V2_0+V2S′
Read level V4c related to threshold voltage distribution S4: V4c 2=V4_0+V4S′
Read level V6c related to threshold voltage distribution S6: V6c 2=V6_0+V6S′

From the above assumption, the numbers of mismatched bits g and h are “g=20” and “h=4”. The dynamic shift value Delta is calculated by logarithmic ratio as follows.

$$\begin{matrix}Delta = {log}_{2} \{ ( g + 1 ) / ( h + 1 ) \} \\ = {log}_{2} ( 20 + 1 ) - {log}_{2} ( 4 + 1 ) \\ = {log}_{2} ( 21 ) - {log}_{2} ( 5 ) \\ = {log}_{2} ( 16 + 5 ) - {log}_{2} ( 4 + 1 )\end{matrix} \qquad ( F 9 )$$

In Formula (F9), considering only the integer part, “log₂ (16)=4” and “log₂ (4)=2” are obtained. Therefore, the integer part of Formula (F9) is expressed by the following Formula (F10).

Integer part of Delta: 4−2=2 (F10)

It should be noted that, in a case where “21” in a decimal number is expressed as a binary number, it is “00010101”, and the position of “1” on the leftmost side is the bit [4] (5th digit). In a case where “5” in a decimal number is expressed as a binary number, it is “00000101”, and the position of “1” on the leftmost side is the bit [2] (third digit).

In Formula (F10), “g” corresponding to the read level being offset to the lower voltage side (minus read level) is larger than “h” corresponding to the read level being offset to the higher voltage side (plus read level). That is, the difference between the standard read data and the plus read data is smaller than the difference between the standard read data and the minus read data. Therefore, in the next read operation for the same address, a decrease in the number of error bits is expected by moving the read level to the higher voltage side.

Using the dynamic shift value Delta obtained by Formula (F10), each of the corrected read levels V2c_3, V4c_3, and V6c_3 for the third read operation is determined as follows.

The read level V2c_2 in the third read operation is calculated as in the following Formula (F11a).

$$\begin{matrix}V 2 c\_ 3 = V 2 c\_ 2 + 1 / 2 \times Delta \\ = V 2 c\_ 2 + 1 / 2 \times 2 \\ = V 2 c\_ 2 + 1\end{matrix} , \qquad ( F 11 a )$$

where considering only the integer part of Formula (F11a), the read level V2c to be corrected is expressed by the following Formula (F11b).

$$\begin{matrix}V 2 c\_ 3 = V 2 c\_ 2 + 1 \\ = V 2 \_ 0 - 1 + 1 \\ = V 2 \_ 0\end{matrix} \qquad ( F 11 b )$$

The read level V4c_3 in the third read operation is calculated as in the following Formula (F12a).

$$\begin{matrix}V 4 c \_ 3 = V 4 c \_ 2 + 1 / 3 \times Delta \\ = V 4 c \_ 2 + 1 / 3 \times 2 \\ = V 4 c\_ 2 + 2 / 3\end{matrix} , \qquad ( F 12 a )$$

where considering only the integer part of Formula (F12a), the read level V4c to be corrected is expressed by the following Formula (F12b).

$$\begin{matrix}V 4 c\_ 3 = V 4 c\_ 2 \\ = V 4 \_ 0 - 3\end{matrix} \qquad ( F 12 b )$$

The read level V6c_3 in the third read operation is calculated as in the following Formula (F13a).

$$\begin{matrix}V 6 c\_ 3 = V 6 c\_ 2 + 7 / 5 \times Delta \\ = V 6 c\_ 2 + 7 / 5 \times 2 \\ = V 6 c\_ 2 + 14 / 5\end{matrix} , \qquad ( F 13 a )$$

where considering only the integer part of Formula (F13a), the read level V6c to be corrected is expressed by the following Formula (F13b).

$$\begin{matrix}V 6 c\_ 3 = V 6 c\_ 2 + 2 \\ = V 6 \_ 0 - 12 + 2 \\ = V 6 \_ 0 - 10\end{matrix} \qquad ( F 13 b )$$

Similarly to the read level corrected according to these automatic adjustment read operations, the read level to be used in the next read operation is calculated based on the number of error bits of the same page at the previous time.

It should be noted that in the present embodiment, the method for comparing “g” and“h” is fixed to any one of the above-described various methods. However, a configuration may be made so that by the setting of a configuration register or the like of the NAND memory 30, a method of comparison, a method of calculating a dynamic shift value of a threshold voltage, coefficients and constants used for calculating the dynamic shift value, and the like can be set and selected.

(b-6) <Sp24>

The NAND memory 30 stores the dynamic shift value of the read level calculated by the correction amount calculation circuit 52 in the register circuit 35.

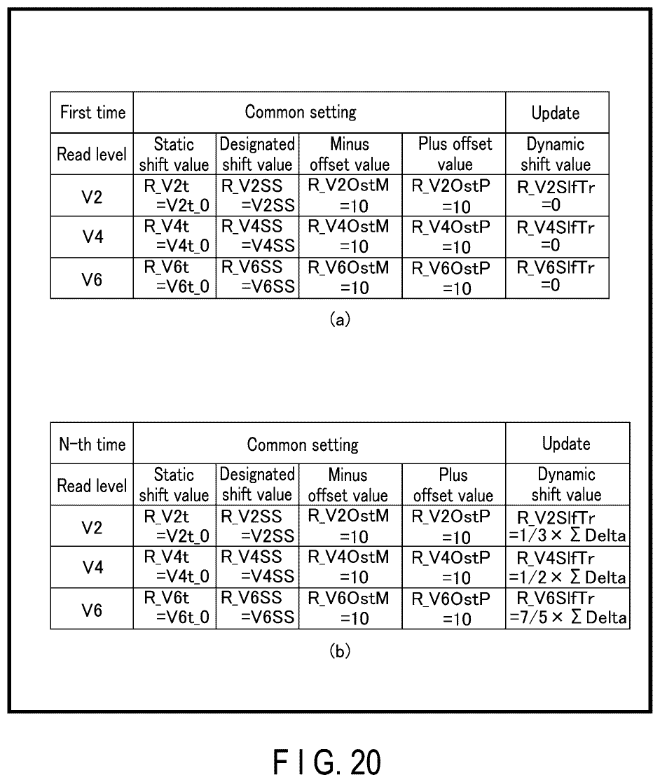

In the register circuit 35, the state of the setting information register 350 is updated as illustrated in FIG. 20.

FIG. 20 is a schematic diagram for illustrating setting information related to a read voltage in the register circuit 35 in the NAND memory 30 in the memory system 1 of the present embodiment.

(a) of FIG. 20 illustrates setting information of various voltages used for the read operation of the middle page stored in the setting information register 350 during the first read operation.

As described above, the read level V2 related to the threshold voltage distribution S2, the read level V4 related to the threshold voltage distribution S4, and the read level V6 related to the threshold voltage distribution S6 are used for reading the middle page.

For the respective read levels V2, V4, and V6, static shift values R_V2c, R_V4c, and R_V6c, designated shift values R_V2SS, R_V4SS, and R_V6SS, minus offset values R_V2OstM, R_V4OstM, and R_V6OstM, and plus offset values R_V2OstP, R_V4OstP, and R_V6OstP are stored in the setting information register 350 as values (register information) of each register of the common setting.

Each of the static shift values R_V2t, R_V4t, and R_V6t is an initial value of a shift value of the read level set based on the manufacturing test of the NAND memory 30. For example, the static shift value R_V2t of the read level V2 is set to “V2t_0”. The static shift value R_V4t of the read level V4 is set to “V4t_0”. The static shift value R_V6t of the read level V6 is set to “V6t_0”.

The designated shift values R_V2SS, R_V4SS, and R_V6SS are the movement amounts of the read levels set by the memory controller 10. For example, the designated shift value R_V2SS of the read level V2 is set to “V2SS”. The designated shift value R_V4SS of the read level V4 is set to “V4SS”. The designated shift value R_V6SS of the read level V6 is set to “V6SS”.

The minus offset values R_V2OstM, R_V4OstM, and R_V6OstM are offset amounts for generating read levels (minus read levels) offset (shifted) to the lower voltage side. For example, the minus offset value R_V2OstM of the read level V2 is set to 10 (10 DAC). The minus offset value R_V4OstM of the read level V4 is set to 10 (10 DAC). The minus offset value R_V6OstM of the read level V6 is set to 10 (10 DAC).

The plus offset values R_V2OstP, R_V4OstP, and R_V6OstP are offset amounts for generating read levels (plus read levels) offset (shifted) to the higher voltage side. For example, the plus offset value R_V2OstP of the read level V2 is set to 10 (10 DAC). The plus offset value R_V4OstP of the read level V4 is set to 10 (10 DAC). The plus offset value R_V6OstP of the read level V6 is set to 10 (10 DAC).

In the present embodiment, the setting information register 350 stores the dynamic shift values R_V2SlfTr, R_V4SlfTr, and R_V6SlfTr determined in the NAND memory 30 as register values. The dynamic shift values R_V2SlfTr, R_V4SlfTr, and R_V6SlfTr are values updated according to the execution of the automatic adjustment read operation.

During the first read operation, the dynamic shift values R_V2SlfTr, R_V4SlfTr, and R_V6SlfTr of the respective read levels V2, V4, and V6 are set to zero (0).

(b) of FIG. 20 illustrates setting information of various voltages used for the read operation of the middle page stored in the setting information register 350 during the N-th read operation.

As illustrated in (b) of FIG. 20, the register values of the common setting such as the static shift values R_V2t, R_V4t, and R_V6t, the designated shift values R_V2SS, R_V4SS, and R_V6SS, the minus offset values R_V2OstM, R_V4OstM, and R_V6OstM, and the plus offset values R_V2OstP, R_V4OstP, and R_V6OstP are not updated according to the automatic adjustment read operation.

The dynamic shift values R_V2SlfTr, R_V4SlfTr, and R_V6SlfTr of the respective read levels V2, V4, and V6 are updated according to the number of automatic adjustment read operations.

During the N-th automatic adjustment read operation, the dynamic shift value R_V2SlfTr of the read level V2 is set to “(1/3)×ΣDelta”. The dynamic shift value R_V4SlfTr of the read level V4 is set to “(1/2)×ΣDelta”. The dynamic shift value R_V6SlfTr of the read level V6 is set to “(7/5)×ΣDelta”, where “ΣDelta” is an added value of the dynamic shift value Delta calculated by each of the first to (N−1)-th automatic adjustment read operations.

As described above, the voltage values of the read levels V2, V4, and V6 are corrected during the reading of the middle page of a certain address based on the dynamic shift values R_V2SlfTr, R_V4SlfTr, and R_V6SlfTr stored in the setting information register 350.

With the above operation, the memory system 1 of the present embodiment calculates the dynamic shift value of the read level inside the NAND memory 30.

It should be noted that, in the present embodiment, an example of calculating the dynamic shift values of the read levels V2, V4, and V6 during the reading of the middle page is illustrated. However, the memory system 1 of the present embodiment can calculate, inside the NAND memory 30, the dynamic shift values of the read levels V1 and V5 used for reading the lower page and the dynamic shift values of the read levels V3 and V7 used for reading the upper page by substantially the same operation and control as those in the above-described example.

### (c) Summary

In a general memory system, a high-speed correction capability of ECC is about the number of hard bit corrections of a low-density parity check (LDPC) code or a correction capability of a BCH code. Therefore, the high-speed correction capability of the error bit is around 1% of the data length at the highest. For example, in a case where the read amount of one time is 4 kByte, the number of correctable bits is about 450 bits in data of about 4.5 kByte including the ECC parity.

The errors of about 450 bits include those in which data written in a higher state between adjacent states is read as data of a lower state and those in which data written in a lower state is read as data of a higher state.

For example, in a case where data is read after the data is left for a long time after the data is written, an error due to data retention stress is expected.

A main cause of an error occurrence of the data retention stress is substantially uniform movement of the threshold voltage distributions according to the data in the NAND memory 30. Therefore, in the error caused by the data retention stress, the collapse or change of the shape of threshold voltage distribution of the data in the NAND memory 30 is small, and the error is caused by the phenomenon of moving from the higher voltage side to the lower voltage side of the threshold voltage distribution and the phenomenon of increasing the distribution width of the threshold voltage distribution (see (b) of FIG. 4).

In the phenomenon in which the threshold voltage distribution moves from the higher voltage side to the lower voltage side, the shape of the threshold voltage distribution is substantially maintained, and the threshold voltage distributions move in parallel from the original voltage range to the lower voltage side.

The phenomenon in which the distribution width of the threshold voltage distribution is expanded is caused by the variations in the movement amount of the threshold voltage from the higher voltage side to the lower voltage side for each memory cell. Therefore, the shape on the higher voltage side of the threshold voltage distribution is substantially maintained, but the shape on the lower voltage side of the threshold voltage distribution changes in a direction in which the slope of the threshold voltage distribution becomes gentle. Even in the phenomenon in which the distribution width of the threshold voltage distribution is expanded, the movement amount of the threshold voltage distribution can be estimated on the assumption that the threshold voltage distribution corresponding to the data changes symmetrically to the higher voltage side and the lower voltage side, and the movement amount of the voltage can be obtained almost accurately.

The memory system 1 of the first embodiment reads data from the memory cell MC using a standard read level and a read level offset from the standard read level in the NAND memory 30. The number of error bits of the read data is detected. The memory system 1 of the first embodiment calculates the dynamic shift value of the read level in the NAND memory 30 based on the detection result of the error bits included in the read data. The memory system 1 of the present embodiment executes the next read operation using the read level corrected based on the calculated dynamic shift value.

Accordingly, the memory system of the present embodiment reduces the number of error bits in the read data acquired by the read operation.

As described above, the memory system of the present embodiment improves the reliability of data reading.

### (2) Second Embodiment

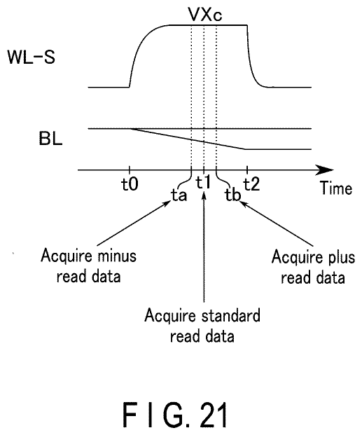

A memory system of a second embodiment will be described with reference to FIG. 21.

FIG. 21 is a schematic diagram for illustrating the acquisition of data during a read operation of the memory system 1 of the second embodiment.

In the first embodiment, in the automatic adjustment read operation, the voltage applied to the selected word line is changed in three stages such as a minus read level, a standard read level, and a plus read level.

For example, minus read data and plus read data may be acquired only by applying the standard read level to the selected word line. This can be achieved by shifting the timing at which the sense amplifier module 39 captures a signal corresponding to the threshold voltage of the memory cell MC into the data latch DL and acquiring a signal corresponding to the threshold voltage of the memory cell MC sensed by applying the read level to the word line WL. Alternatively, this may be achieved by acquiring a signal corresponding to the threshold voltage of the memory cell MC by detecting the current of the bit line BL.

In the memory system 1 of the second embodiment, in the determination of the threshold voltage of the memory cell MC related to a certain threshold voltage distribution, the read level applied to the selected word line WL-S is the read level VXc for standard reading. It should be noted that the read level to be applied to the selected word line WL-S may be a read level offset from the standard read level to the higher voltage side.

In FIG. 21, the vertical axis represents the magnitude of the voltage, and the horizontal axis represents time. At a time t0, the application of the standard read level VXc to the selected word line WL-S is started. By the application of the standard read level VXc, the voltage of the selected word line WL-S increases.

In response to the application of the read level VXc related to a certain threshold voltage distribution, the memory cell MC responds (on/off). In a case where the memory cell MC is turned on, a current is generated in the bit line BL according to the response speed (driving force) of the memory cell MC, and the potential of the bit line BL changes. In a case where the memory cell MC is turned off, the bit line BL maintains the state of charge, and the voltage does not change.

At a time t1, the sense amplifier module 39 senses the voltage of the memory cell MC and captures the sensed result into the data latch DL as standard read data. The time t1 is, for example, 10.00 μs.

At a time ta that is a timing earlier than the time t1, the sense amplifier module 39 senses the voltage of the memory cell MC and captures the sensed result into the data latch EDL as minus read data. The time ta is, for example, 9.95 μs. Accordingly, minus read data (data substantially equivalent to the minus read data) is acquired.

Similarly to this, at a time tb that is a timing later than the time t1, the sense amplifier module 39 senses the voltage of the memory cell MC and captures the sensed result into the data latch FDL as plus read data. The time tb is, for example, 10.05 μs. Accordingly, plus read data (data substantially equivalent to the plus read data) is acquired.

At a time t2, the application of the read level VXc is stopped. The determination of the threshold voltage of the memory cell MC by the read level VXc ends.

Similarly also for the read level related to each threshold voltage distribution, each of the minus read data, the standard read data, and the plus read data is acquired by shifting the signal sense timing.

As described above, the memory system 1 of the second embodiment can acquire the minus read data and the plus read data without applying the read level offset from the standard read level.

Accordingly, the read latency of the memory system 1 of the second embodiment can be made substantially the same as the read latency of the memory system that does not calculate a correction value of the read level during the read operation.

Therefore, according to the second embodiment, the read data can be output from the NAND memory 30 to the memory controller 10 with a latency substantially equivalent to a normal read operation of reading data only at the standard read level.

As described above, the memory system 1 of the second embodiment obtains substantially the same effects as the effects of the first embodiment and improve the performance of the memory system.

### (3) Third Embodiment

A memory system of a third embodiment will be described.

In the first embodiment and the second embodiment, the number of “1”s of the verification data stored in the data latch GDL and the number of “1”s of the verification data stored in the data latch HDL are counted within the data range (for example, in units of 8 bits) collectively output from the NAND memory 30.

Here, the number of “1”s in the verification data may be counted in the entire data for one page or a portion having a size larger than I/O units.

Also in this case, the memory system of the third embodiment obtains substantially the same effects as those of the memory systems of the above-described embodiments.

### (4) Fourth Embodiment

A memory system of a fourth embodiment will be described.

In the NAND memory 30, various kinds of stress for changing the threshold voltage distribution occur.

In a case where a dynamic shift value of the read level only needs to be calculated only by the error of specific stress, for example, in a case of corresponding to only the data retention, it only needs to be considered that the threshold voltage distribution shifts only in the lower voltage direction. In this case, the plus read data according to the read level offset to the higher voltage side does not necessarily need to be read.

That is, only the number of “1”s (g) obtained from the XOR operation on the standard read data and the minus read data may be measured by acquiring the standard read data and the minus read data without acquiring the plus read data.

The necessity of correction of the read level by the dynamic shift value and the magnitude of the dynamic shift value of the read level are determined based on the measured number “g” of “1”s and the magnitude “L” of the threshold. For example, the threshold is a value set in advance at the time of shipment of the memory system. The threshold “L” is a natural number.

For example, in a case where “g” is 0 (in a case where all the bits of the standard read data and the minus read data match), the NAND memory 30 determines that the correction of the read level by the dynamic shift value is not needed. At this time, the dynamic shift value is set to zero, and the read level is corrected by the shift value including only the designated shift value and the static shift value. In a case where “g” is “L” or more, the NAND memory 30 determines that the correction of the read level by the dynamic shift value is necessary. In a case where “g” is zero or more and less than “L”, the NAND memory 30 determines that the correction of the read level by the dynamic shift value is not necessary.

As described above, the NAND memory 30 calculates the dynamic shift value corresponding to the magnitude of “g”. The read level is corrected by the shift value including the calculated dynamic shift value.

Also in this case, the memory system of the fourth embodiment obtains substantially the same effects as those of the memory systems of the above-described embodiments.

### (5) Fifth Embodiment

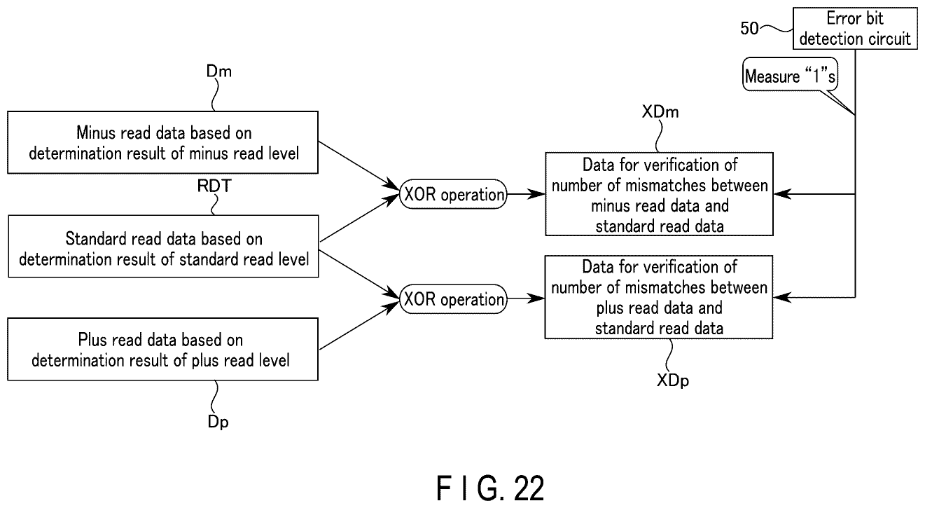

A memory system of a fifth embodiment will be described with reference to FIG. 22.

FIG. 22 is a schematic diagram for illustrating a memory system 1 of a fifth embodiment.

In the first to fourth embodiments, the number of error bits included in the data is verified by performing an OR operation on the results of the XOR operation on the standard read data, the minus read data, and the plus read data for each group of a plurality of read levels of a certain page (for example, the middle page).

As illustrated in FIG. 22, in the fifth embodiment, the standard read data RDT, the minus read data Dm, and the plus read data Dp are generated using the read levels related to the respective threshold voltages of the page to be a read target.

Thereafter, the data XDm indicating the result of the XOR operation on the standard read data RDT and the minus read data Dm and the data XDp indicating the result of the XOR operation on the standard read data RDT and the plus read data Dp are generated.

The number of “1”s included in each of the generated verification data XDm and XDp for one page is counted by the error bit detection circuit 50.

In the fifth embodiment, the NAND memory 30 calculates the dynamic shift value of the read level so as to shift the read level according to the verification data XDm and XDp in which the number of “1”s is small.

It should be noted that the NAND memory 30 may set a dynamic shift value for shifting the read level in a predetermined direction based on expected stress (data retention, read disturb, or the like) and the number of “1”s. Regarding the dynamic shift value with respect to data retention, on the lower voltage side, a dynamic shift value proportional to the difference in the number of “1”s is provided to the read level. Regarding the dynamic shift value of the read disturb, for example, in the lower page, the dynamic shift value proportional to the difference in the number of “1”s on the higher voltage side is provided only to the read level V1 in the “A” state.

Also in this case, the memory system of the fifth embodiment obtains substantially the same effects as those of the memory systems of the above-described embodiments.

### (6) Sixth Embodiment

A memory system of a sixth embodiment will be described.

In the first to fifth embodiments, the dynamic shift value of the read level has been calculated using a fractional multiple of the difference Delta between the number of mismatches between the determination result of the minus read level and the determination result of the standard read level and the number of mismatches between the determination result of the plus read level and the determination result of the standard read level.

In order to simplify the configuration of the hardware mounted on the NAND memory 30, the value of the denominator of the fractional multiple for calculating the difference Delta may be limited to a power of 2.

Since the denominator is limited to a power of 2, the operator for implementing the calculation of the dynamic shift value inside the NAND memory 30 can be configured only by the shift operation of the operation and the addition of integers.

In order to approximate the dynamic shift value of the read level by an operation of the reciprocal of a power of 2, the following processing is executed.

(Step 1) The denominator of the correction coefficient is multiplied by an integer so that the value of the denominator is set to a value close to a power of 2 smaller than four times the denominator
(Step 2) The numerator of the correction coefficient is multiplied by the same value as the value by which the denominator is multiplied in step 1
(Step 3) The value of the denominator of the correction coefficient is replaced with a power of 2 smaller than four times the denominator, and the value obtained in step 2 is used as the value of the numerator of the correction coefficient
(Step 4) The fraction obtained in step 3 is expressed by a sum of terms of the form 1/(a power of 2)

In a case where the dynamic shift value (correction coefficient) in the first embodiment described above is used as an example, the processing in steps 1 to 4 described above is more specifically described as follows.

### Dynamic Shift Value Before Processing:

Dynamic shift value of read level V2 related to threshold voltage distribution S2: (1/3)×Delta
Dynamic shift value of read level V4 related to threshold voltage distribution S4: (1/2)×Delta
Dynamic shift value of read level V6 related to threshold voltage distribution S6: (7/5)×Delta

Note that, the dynamic shift value of each read level includes only an integer part of a fraction.

By the processing of steps 1 to 4 described above, the dynamic shift value of each read level is processed as follows.

By the processing in steps 1 and 2, with respect to the dynamic shift value “(1/3)×Delta” at the read level V2, the numerator and the denominator of the correction coefficient are multiplied by “3”. Accordingly, the parameter of the dynamic shift value of the read level V2 becomes “(3/9)×Delta”.

By the processing in step 3, “9” of the denominator of the correction coefficient is replaced with “8”. Accordingly, the parameter of the dynamic shift value of the read level V2 becomes “(3/8)×Delta”.

By the processing in step 4, when the correction coefficient is expressed by a sum of reciprocals of powers of 2, the parameter of the dynamic shift value is expressed as “(1/4+1/8)×Delta”.

As a result, the dynamic shift value of the read level V2 is a value expressed by the sum of a value obtained by rightward shifting the Delta value (binary value) by two bits and a value obtained by rightward shifting the Delta value by three bits.

The dynamic shift value “(1/2)×Delta” at the read level V4 is expressed by the reciprocal of a power of 2. Therefore, the processing in steps 1 to 4 is not executed on the dynamic shift value of the read level V4.

The dynamic shift value of the read level V4 is a value obtained by rightward shifting the Delta value by one bit.

By the processing in steps 1 and 2, with respect to the dynamic shift value “(7/5)×Delta” at the read level V6, the numerator and the denominator of the correction coefficient are multiplied by “3”. Accordingly, the parameter of the dynamic shift value becomes “(21/15)×Delta”.

By the processing in step 3, “15” of the denominator is replaced with “16”. Accordingly, the parameter of the dynamic shift value becomes “(21/16)×Delta”.

By the processing in step 4, when the correction coefficient is expressed by a sum of reciprocals of a power of 2, the parameter of the dynamic shift value is expressed as “(1+1/4+1/16)×Delta”.

As a result, the dynamic shift value of the read level V6 is a value expressed by the sum of a value obtained by rightward shifting the Delta value by two bits and a value obtained by rightward shifting the Delta value by four bits.

As described above, the dynamic shift value of each of the read levels V2, V4, and V6 is calculated.

The dynamic shift value calculation processing is not limited to the above example. For example, the dynamic shift value calculation processing may be executed with the approximate denominator fixed to “16”.

(Step 1a) The denominator of the correction coefficient is multiplied by an integer so that the value of the denominator is set to a value close to “16”
(Step 2a) The numerator of the correction coefficient is multiplied by the same value as the value by which the denominator is multiplied in step 1a
(Step 3a) The value of the denominator of the correction coefficient is replaced with “16”, and the value obtained in step 2a is used as the value of the numerator of the correction coefficient
(Step 4a) The fraction obtained in step 3a is expressed by a sum of terms of the form 1/(a power of 2)

In a case where the dynamic shift value (correction coefficient) in the first embodiment described above is used as an example, the processing in steps 1a to 4a described above is more specifically described as follows.

### Dynamic Shift Value Before Processing:

Dynamic shift value of read level V2 related to threshold voltage distribution S2: (1/3)×Delta
Dynamic shift value of read level V4 related to threshold voltage distribution S4: (1/2)×Delta
Dynamic shift value of read level V6 related to threshold voltage distribution S6: (7/5)×Delta

Note that, the dynamic shift value of each of the read levels V2, V4, and V6 includes only an integer part of a fraction.

By the processing of steps 1a to 4a described above, the dynamic shift value of each read level is processed as follows.

By the processing in steps 1a and 2a, with respect to the dynamic shift value “(1/3)×Delta” at the read level V2, the numerator and the denominator of the correction coefficient are multiplied by “5”. Accordingly, the parameter of the dynamic shift value becomes “(5/15)×Delta”.

By the processing in step 3a, the value of the denominator of the correction coefficient is replaced from “15” to “16”. Accordingly, the parameter of the dynamic shift value becomes “(5/16)×Delta”.

By the processing in step 4a, when the correction coefficient is expressed by a sum of reciprocals of powers of 2, the parameter of the dynamic shift value is expressed as “(1/4+1/16)×Delta”.

As a result, the dynamic shift value of the read level V2 is the sum of a value obtained by rightward shifting the Delta value (binary value) by two bits and a value obtained by rightward shifting the Delta value by four bits.

The dynamic shift value “(1/2)×Delta” at the read level V4 is expressed by the reciprocal of a power of 2. Therefore, the processing in steps 1a to 4a is not executed on the dynamic shift value of the read level V4.

Therefore, the dynamic shift value of the read level V4 is a value obtained by rightward shifting the Delta value by one bit.

By the processing in steps 1a and 2a, with respect to the dynamic shift value “(7/5)×Delta” at the read level V6, the numerator and the denominator of the correction coefficient are multiplied by “3”. Accordingly, the parameter of the dynamic shift value becomes “(21/15)×Delta”.

By the processing in step 3a, the value of the denominator of the correction coefficient is replaced from “15” to “16”. Accordingly, the parameter of the dynamic shift value becomes “(21/16)×Delta”.

By the processing in step 4a, when the correction coefficient is expressed by a sum of reciprocals of powers of 2, the parameter of the dynamic shift value is expressed as “(1+1/4+1/16)×Delta”.

As a result, the dynamic shift value of the read level V6 is the sum of a value obtained by rightward shifting the Delta value by two bits and a value obtained by rightward shifting the Delta value by four bits.

As described above, the memory system 1 of the sixth embodiment can simplify the configuration of the NAND memory 30 by expressing the dynamic shift value of the read level as values of powers of 2.

Also in this case, the memory system 1 of the sixth embodiment obtains substantially the same effects as those of the memory systems of the first to fifth embodiments.

### (7-1) Seventh Embodiment

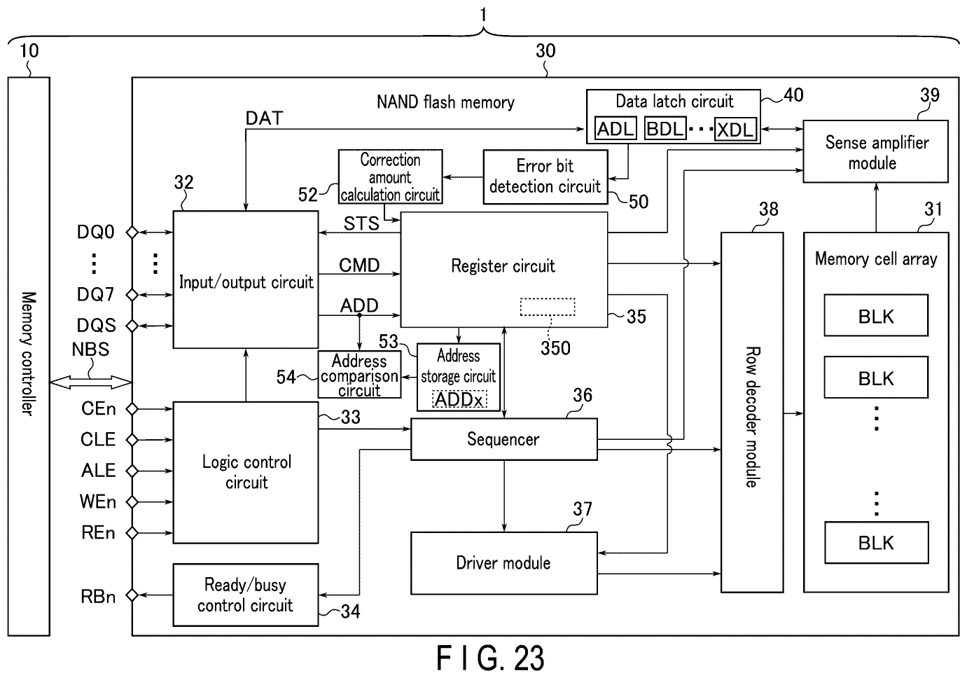

A memory system of a seventh embodiment will be described with reference to FIG. 23.

FIG. 23 is a block diagram illustrating a configuration example of the NAND memory 30 in the memory system 1 of the seventh embodiment.

In general, in a case where data is written to a plurality of addresses almost simultaneously in the physical block of the NAND memory, there is a high possibility that the memory cell MC at the address where the data has been written is subjected to similar stress. Therefore, if the block addresses are the same, the error bits in the read data can be reduced by the read operation using the corrected read level even if the word line addresses are different.

As illustrated in FIG. 23, in the memory system 1 of the seventh embodiment, the NAND memory 30 includes an address storage circuit 53 and an address comparison circuit 54.

The address storage circuit 53 is a circuit that stores an address ADDx at which a read command of the automatic adjustment read operation has been issued in the past. The address storage circuit 53 may store a part (for example, a block address) of the past address ADDx. For example, the block address is included in the most significant bit (MSB) side portion of the address ADD and the past address ADDx.

The address comparison circuit 54 is a circuit that compares the address stored in the address storage circuit 53 with the received address ADD. The address comparison circuit 54 compares a part (for example, an upper part of an address corresponding to the block BLK of the NAND memory 30) of the past address ADDx corresponding to the read command (“C4h”) of the past automatic adjustment read operation in the address storage circuit 53 with a part of the address ADD corresponding to the read command of the read operation performed after the correction of the read level, and determines whether the addresses match. Furthermore, the address comparison circuit 54 compares a specific part of the past address ADDx corresponding to the read command (“C4h”) of the past automatic adjustment read operation in the address storage circuit 53 with a specific part of the address ADD corresponding to the read command of the read operation performed after the correction of the read level, and determines whether the addresses match. The specific part of the address is included in a part of the address. The address comparison circuit 54 notifies the sequencer 36 of a determination result based on the comparison between the address ADD and the past address ADDx.

The sequencer 36 reads the setting information related to the read level in the setting information register 350 based on the notification of the comparison result from the address comparison circuit 54. The sequencer 36 sets the drive mode of the charge pump of the driver module 37 using the read setting information.

In a case where a part of the address ADD matches a part of the past address ADDx, the NAND memory 30 executes the read operation from the area indicated by the address ADD using the read level (read voltage) including the dynamic shift value obtained by the automatic adjustment read operation.

In a case where a part of the address ADD does not match a part of the past address ADDx, the NAND memory 30 executes the read operation from the area indicated by the address ADD using the read level before correction by the automatic adjustment read operation.

In a case where the specific part of the address ADD does not match the specific part of the past address ADDx, the NAND memory 30 reads data from the area indicated by the address ADD using the read level based on the register value of “ViC=R_V1 0+R_Vit+R_ViSS”.

In a case where the specific part of the address ADD matches the specific part of the past address ADDx, the block BLK storing the data to be read by the address ADD is the block BLK on which the automatic adjustment read operation has been executed. For example, in the configuration of the setting information register 350 in the first embodiment, the NAND memory 30 reads data from the area indicated by the address ADD using the read level including the dynamic shift value by the register value of “ViC=R_V1 0+R_ViC+R_ViSS+R_ViS SlfTr”.

As described above, in the present embodiment, in a case where the block address of the selected address ADD matches the block address of the address ADDx of the address storage circuit 53, data is read from the memory cell MC in the block BLK to be a reading target using the read level corrected by the automatic adjustment reading. Accordingly, read data having a small number of error bits can be acquired.

The memory system 1 of the seventh embodiment corrects the read level by comparing the addresses and improve the efficiency and reliability of the read operation.

### (7-2) Further Embodiment of Seventh Embodiment

In general, characteristics of memory cells in the same chip of the NAND memory tend to have a relatively small difference in characteristics between blocks and a large difference in characteristics between word lines. In the memory cell array 31, there is a high possibility that the memory cells MC of the plurality of word lines WL having close physical positions have similar characteristics. Therefore, in the read operation targeting the word line WL on which the automatic adjustment read operation is not performed, the error bits in the read data can be reduced by using the corrected read level obtained from the word line WL physically close to the target word line WL and on which the automatic adjustment read operation has been performed.

Therefore, the specific part of a part of the address ADD and the specific part of a part of the past address ADDx of the seventh embodiment may be, for example, a word line address.

In the memory system 1 of the further embodiment of the seventh embodiment, the address storage circuit 53 stores a part of the past address ADDx. A part of the past address ADDx is, for example, a word line address. The word line address is included in a portion between the block address and the column address (bit line address) of the address ADD and the past address ADDx.

The address comparison circuit 54 compares the past address ADDx with the address ADD and determines whether or not parts of the addresses match.

In the further embodiment of the seventh embodiment, in a case where the word line address (or a part of the word line address) of the selected address ADD matches the word line address of the address ADDx of the address storage circuit 53, data is read from the memory cell MC of the word line WL to be a read target using the read level corrected by the automatic adjustment reading. Accordingly, read data having a small number of error bits can be acquired.

It should be noted that whether or not to use the read level corrected by the automatic adjustment reading may be determined by several upper (MSB side) bits of the word line address.

It should be noted that the specific parts of the addresses ADD and ADDx are not limited to the above example. The specific parts of the addresses ADD and ADDx may be portions corresponding to physical addresses. The specific parts of the addresses ADD and ADDx may be obtained by explicitly designating an address mask register (not illustrated) by a Set Feature command or the like.

Accordingly, the memory system 1 of the further embodiment of the seventh embodiment corrects the read level by comparing the addresses and improve the efficiency and reliability of the read operation.

The memory system 1 of the seventh embodiment obtains substantially the same effects as those of the memory systems of the above-described embodiments.

### (8) Eighth Embodiment

A memory system of an eighth embodiment will be described.

As in the first to seventh embodiments, the memory system 1 of the present embodiment calculates a dynamic shift value of a read level used during a read operation on a certain address ADD by an automatic adjustment read operation.

The memory system 1 of the eighth embodiment executes the read operation using the read level including the dynamic shift value calculated by the automatic adjustment read operation of the previous cycle during the read operation of the next cycle on the same address ADD.

Accordingly, the memory system 1 of the eighth embodiment obtains substantially the same effects as those of the memory systems of the above-described embodiments.

### (9) Ninth Embodiment

A memory system of a ninth embodiment will be described.

In the memory systems 1 of the first to eighth embodiments, as described above, the NAND memory 30 executes the XOR operation on the standard read data, the minus read data, and the plus read data for each group of a plurality of read levels (for example, the read levels V2, V4, and V6 of the middle page) of a certain page, further executes the OR operation on the data indicating the result of the XOR operation, and counts and compares the number of “1”s in the data based on the data of the result of the OR operation.

In the ninth embodiment, the NAND memory 30 corrects the specific one or more read levels without correcting all the read levels based on the count of “1”s in the data and the comparison result of the number of “1”s.

For example, the NAND memory 30 calculates only the dynamic shift value of the read level V1 among the two read levels V1 and V5 for reading the lower page during the automatic adjustment read operation on the lower page.

In the stress condition of the read disturb, the number of errors detected by the threshold voltage of the memory cell MC moving from the threshold voltage distribution (erase state) S0 to the threshold voltage distribution (A state) S1 is large.

Therefore, in the correction of the read level of the lower page, it is effective to compare and detect the error bits (“1”s in the data) of the read level V1 related to the threshold voltage distribution S1.

In addition, in the read disturb, the number of errors detected by the threshold voltage of the memory cell MC moving from the threshold voltage distribution S0 to the threshold voltage distribution S1 tends to be overwhelmingly larger than the number of errors detected by the threshold voltage of the memory cell MC moving from the threshold voltage distribution S1 to the threshold voltage distribution S0.

Therefore, regarding the read level V1 of the lower page, the number of errors in which the threshold voltage of the memory cell MC moves from the lower threshold voltage distribution S0 to the upper threshold voltage distribution S1, that is, the number (h) of error bits in the plus read level V1p offset to the higher voltage side with respect to the standard read level Vic is larger than the number (g) of error bits in the minus read level V1m offset to the lower voltage side with respect to the standard read level Vic.

Furthermore, in a case where the threshold voltage of the memory cell MC to store data corresponding to the threshold voltage distribution S0 moves to an area on the higher voltage side of the threshold voltage distribution S1 or a distribution equal to or higher than the threshold voltage distribution S2, there may also be a case where the value does not change even if the read operation in which the read level is shifted is executed. In this case, even if an error bit occurs, the error bit is not reflected in either “g” or “h”.

Therefore, regarding a specific error, there is also a case where the number of error bits of the read data cannot be reduced even if all the read levels are corrected.

Therefore, by correcting only a specific read level as in the ninth embodiment, the load of the operation of the NAND memory 30 can be suppressed.

It should be noted that in the ninth embodiment, either the comparison between the minus read data and the standard read data or the comparison between the plus read data and the standard read data is not executed. In a case where the shift amount (dynamic shift value) of the read level is excessive, there is a possibility that the dynamic shift value cannot be corrected in a direction of decreasing the shift amount of the read level. Therefore, the lower limit value may be set to the number of “1”s included in the result of the XOR operation on the standard read data and the read data at the offset read level.

In this case, in a case where the number of “1”s (the number of error bits) included in the result of the XOR operation (verification data) is smaller than the lower limit value, the read level is not corrected. In a case where the number of “1”s included in the result of the XOR operation is equal to or larger than the lower limit value, the read level is corrected. Accordingly, the memory system of the ninth embodiment prevents excessive correction of the read level.

It should be noted that, regarding the same page, in a case where the number of “1”s in the result of the XOR operation on the (N+1)-th standard read data and the offset read data is larger than the number of “1”s in the result of the XOR operation on the N-th standard read data and the offset read data, the correction value of the read level may be controlled so that the correction value based on the result of the N-th XOR operation is returned to the correction value based on the results of the XOR operation up to (N−1)-th. Accordingly, excessive correction of the read level is prevented.

As described above, the memory system of the ninth embodiment can efficiently correct the read level.

The memory system of the ninth embodiment obtains substantially the same effects as those of the first to eighth embodiments.

### (10) Tenth Embodiment

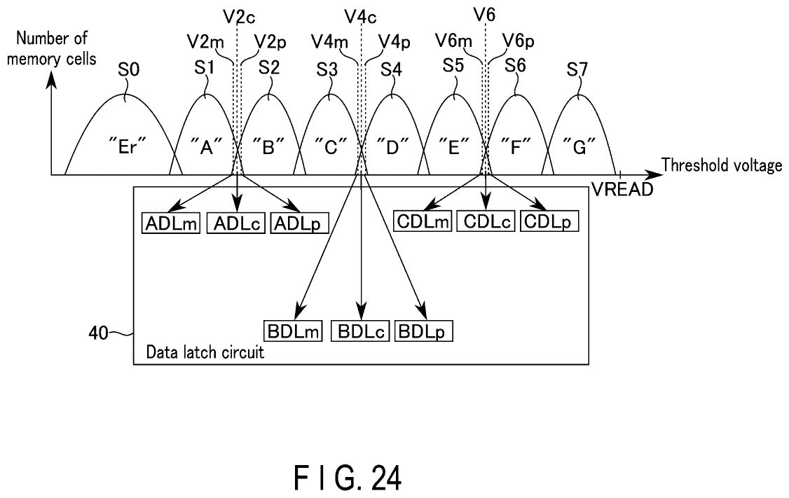

A memory system of a tenth embodiment will be described with reference to FIG. 24.

FIG. 24 is a block diagram illustrating a configuration example of data latches of the NAND memory 30 in the memory system 1 of the tenth embodiment.

In the first to ninth embodiments, in order to reduce the number of pieces of hardware such as the data latches and/or the counters mounted in the NAND memory 30, the processing of further performing the OR operation on the results of the XOR operation on the plurality of pieces of data for each group of the plurality of read levels has been executed.

As illustrated in FIG. 24, in the tenth embodiment, the number of data latches DL may be increased so that the determination result by each of the offset read levels can be stored.

For example, the number of read levels of the middle page in the TLC mode is three. Since the read level offset to the lower voltage side and the read level offset to the higher voltage side are set with respect to the standard read level of each read level, nine data latches DL are mounted in the data latch circuit 40.

Three data latches ADLc, ADLm, and ADLp are provided for the read levels V2 (V2c, V2m, and V2p). Three data latches BDLc, BDLm, and BDLp are provided for the read levels V4 (V4c, V4m, and V4p). Three data latches CDLc, CDLm, and CDLp are provided for the read levels V6 (V6c, V6m, and V6p).

As described above, the number of data latches DL increases by a multiple of the read level.

As described above, by preparing the data latch DL for each read level, the voltage value can be corrected independently for each read level.

In the tenth embodiment, by increasing the number of data latches DL according to the number of read levels, the number of error bits in the result of the XOR operation on the standard read data and the offset read data can be counted during data output from the NAND memory 30 to the memory controller 10 for each read level.

It should be noted that the memory system 1 of the tenth embodiment can also address a situation in which, for example, the threshold voltage distribution S1 moves the read level only to the higher voltage side according to the read disturb, and the other threshold voltage distributions move the read level only to the lower voltage side according to the data retention.

The memory system 1 of the tenth embodiment can flexibly address the calculation of the dynamic shift value of each read level according to the situation of detecting the error bit.

As described above, the memory system 1 of the tenth embodiment obtains the same effects as those of the first to ninth embodiments.

### (11) Eleventh Embodiment

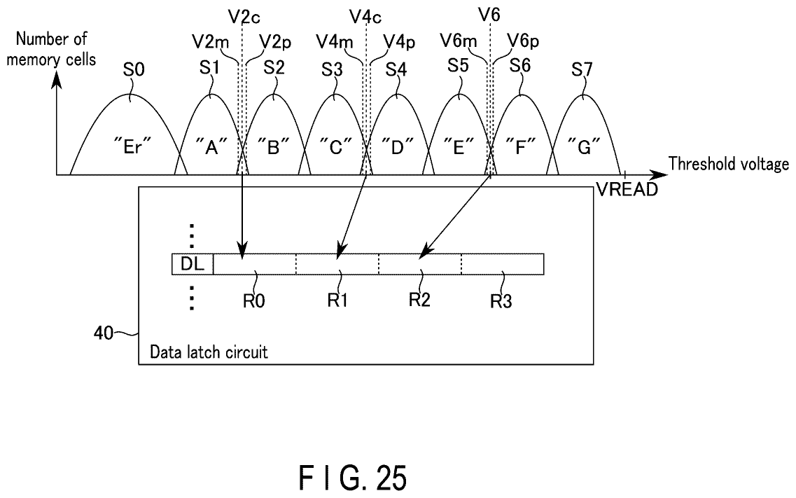

A memory system of an eleventh embodiment will be described with reference to FIG. 25.

FIG. 25 is a schematic diagram for illustrating a memory system 1 of an eleventh embodiment.

In the first to tenth embodiments, in order to simplify the description, the difference between the standard read data and the minus read data (the result of the XOR operation and the OR operation) and the difference between the standard read data and the plus read data (the result of the XOR operation and the OR operation) are calculated for the entire page data. The entire page data is, for example, 16 kByte.

In general, it is expected that data written to the NAND memory 30 is randomized.

Therefore, if the difference in the characteristics of the memory cell MC depending on the position in the memory cell array 31 can be ignored, the position of the bit output from the input/output circuit 32 and the position of the bit for counting the error bit, both in the same page, may not be the same.

The verification data for detecting the error bit may be a part of page data, for example, data (for example, ECC frame data) having a data size of 4.5 kByte including a data portion of 4 kByte and an ECC parity portion of 0.5 kByte. However, the size of the data is preferably a size in which statistical variations can be ignored.

In the eleventh embodiment, as illustrated in FIG. 25, for example, each of the data latches EDL, FDL, GDL, and HDL is divided into four regions R0, R1, R2, and R3.

For example, the data of the determination result of the first read level (standard read level or offset read level) is stored in the region R0 of 4.5 kByte which is the head among the four divided regions R0, R1, R2, and R3 of a certain data latch DL. The data of the determination result of the first read level is, for example, data of the determination result related to the read level V2 of the middle page in the TLC mode. The data of the determination result of the second read level is stored in the second region R1 of 4.5 kByte. The data of the determination result of the second read level is, for example, data of the determination result related to the read level V4 of the middle page in the TLC mode. The data of the determination result of the third read level is stored in the third region R2 of 4.5 kByte. The data of the determination result of the third read level is, for example, data of the determination result related to the read level V6 of the middle page in the TLC mode.

The reading units of data may vary for each application and/or for each use. The number of error bits between the standard read data and the offset read data tends to be proportional to the amount of data to be read. Therefore, the dynamic shift value of the read level may be adjusted according to the data amount by designating the data amount to be read from the memory controller 10 or counting the data amount output from the NAND memory 30.

As described above, the memory system 1 of the eleventh embodiment obtains the same effects as those of the first to tenth embodiments.

### (12) Others

In the memory system of the above-described embodiments, the configuration and the operation for the NAND memory in the TLC mode are exemplified. However, in the memory system of any of the embodiments, the NAND memory 30 may store data in the MLC mode, the QLC mode, or the PLC mode. Even in a case where the memory system of any of the embodiments includes a NAND memory other than the TLC mode, the memory system of the embodiment obtains substantially the same effects as those of the above-described embodiments.

In the above-described embodiments, the threshold voltage distribution of each page is determined from a low read level. However, in the memory system of any of the embodiments, the threshold voltage distribution may be determined from a high read level.

In the above-described embodiments, the N-th read operation and the (N+1)-th read operation are described as continuous accesses. The memory system (and the control method thereof) of any of the embodiments may be applied to access including an N-th read operation and an (N+1)-th read operation for a specific page (for example, middle page).

In a case where the target page (for example, the middle page) of the N-th read operation and the target page (for example, the upper page) of the (N+1)-th read operation are different, the correction value of the read level related to the target page of the (N+1)-th reading may be estimated based on linear interpolation or extrapolation of the shift value of each read level by using the correction value of the read level related to the target page of the N-th read operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory device including a plurality of memory cells for storing data; and
a memory controller configured to control an operation of the memory device,
wherein the memory device is configured to:
acquire, in response to a first read command set, a first determination result of threshold voltages of the memory cells based on a first read level related to a first threshold voltage distribution and a second determination result of threshold voltages of the memory cells based on a first lower-voltage side offset read level, the first lower-voltage side offset read level is obtained by offsetting the first read level to a lower-voltage side,
acquire a first number of mismatches between the first determination result and the second determination result, and
calculate a first correction amount of the first read level based on the first number of mismatches.

2. The memory system according to claim 1, wherein the memory device is further configured to:
acquire a third determination result of threshold voltages of the memory cells based on a first higher-voltage side offset read level, the first higher-voltage side offset read level is obtained by offsetting the first read level to a higher-voltage side,
acquire a second number of mismatches between the first determination result and the third determination result, and
calculate the first correction amount according to a magnitude relationship between the first number of mismatches and the second number of mismatches.

3. The memory system according to claim 2,
wherein in a case where the first number of mismatches is larger than the second number of mismatches, the memory device is configured to set the first correction amount to a value for shifting the first read level to the higher-voltage side, and
wherein in a case where the first number of mismatches is smaller than the second number of mismatches, the memory device is configured to set the first correction amount to a value for shifting the first read level to the lower-voltage side.

4. The memory system according to claim 2, wherein the memory device is configured to calculate the first correction amount based on a difference between the first number of mismatches and the second number of mismatches.

5. The memory system according to claim 2, wherein the memory device is configured to calculate the first correction amount based on a ratio between the first number of mismatches and the second number of mismatches.

6. The memory system according to claim 2, wherein the memory device is configured to calculate the first correction amount based on a logarithmic ratio between the first number of mismatches and the second number of mismatches.

7. The memory system according to claim 2, wherein the memory device is configured to calculate the first correction amount based on a bilinear expression between the first number of mismatches and the second number of mismatches.

8. The memory system according to claim 1, wherein the memory device is configured to calculate the first correction amount in parallel with an output of the data based on the first determination result.

9. The memory system according to claim 1, wherein the memory device is further configured to:
execute a first exclusive OR operation on the first determination result and the second determination result; and
acquire the first number of mismatches based on a number of “1”s in a result of the first exclusive OR operation.

10. The memory system according to claim 9, wherein the memory device is further configured to:
acquire a fourth determination result of threshold voltages of the memory cells and a fifth determination result of threshold voltages of the memory cells,
the fourth determination result based on a second read level related to a second threshold voltage distribution,
the second read level is different from the first threshold voltage distribution,
the fifth determination result based on a second lower-voltage side offset read level,
the second lower-voltage side offset read level is obtained by offsetting the second read level to a lower-voltage side;
execute a second exclusive OR operation on the fourth determination result and the fifth determination result;
execute an OR operation on a result of the first exclusive OR operation and a result of the second exclusive OR operation;
acquire a third number of mismatches between any two of the first, second, fourth, and fifth determination results based on a number of “1”s in a result of the OR operation; and
calculate the first correction amount and a second correction amount at the second read level based on the third number of mismatches.

11. The memory system according to claim 1, wherein the first read command set includes:
a first command instructing the memory device to calculate the first correction amount, and
a second command that is sent after the first command and instructs the memory device to execute a read operation.

12. The memory system according to claim 1, wherein the memory device further includes:
a first data latch that stores the first determination result;
a second data latch that stores the second determination result; and
a third data latch that stores a result of a first exclusive OR operation on the first determination result and the second determination result.

13. The memory system according to claim 12, wherein the memory device is further configured to:
acquire a fourth determination result of threshold voltages of the memory cells and a fifth determination result of threshold voltages of the memory cells,
the fourth determination result based on a second read level related to a second threshold voltage distribution,
the second read level is different from the first threshold voltage distribution,
the fifth determination result based on a second lower-voltage side offset read level,
the second lower-voltage side offset read level is obtained by offsetting the second read level to a lower-voltage side;
store the fourth determination result in a fourth data latch;
store the fifth determination result in the second data latch,
execute a second exclusive OR operation on the fourth determination result and the fifth determination result,
execute an OR operation on a result of the first exclusive OR operation and a result of the second exclusive OR operation, and
store a result of the OR operation in the third data latch.

14. The memory system according to claim 1, wherein the memory device further includes an error bit detection circuit that counts the first number of mismatches.

15. The memory system according to claim 1, wherein the memory device further includes a correction amount calculation circuit that calculates the first correction amount based on the first number of mismatches.

16. The memory system according to claim 1,
wherein the memory device further includes:
an address storage circuit that stores a first address included in the first read command set, and
an address comparison circuit that compares the first address with a second address included in a second read command set different from the first read command set, and
wherein, in a case where a first portion of the first address matches with a second portion of the second address, the memory device is configured to determine the threshold voltage of the memory cell using a third read level including the first correction amount.

17. The memory system according to claim 1, wherein the memory device further includes:
a first register that stores an offset amount of the first lower-voltage side offset read level, and
a second register that stores the first correction amount.

18. A memory device comprising:
a plurality of memory cells configured to store data; and
a control circuit configured to control operations of the memory cells,
wherein the control circuit is configured to:
acquire, in response to a first read command set, a first determination result of threshold voltages of the memory cells based on a first read level related to a first threshold voltage distribution and a second determination result of threshold voltages of the memory cells based on a first lower-voltage side offset read level, the first lower-voltage side offset read level is obtained by offsetting the first read level to a lower-voltage side;
acquire a first number of mismatches between the first determination result and the second determination result; and
calculate a first correction amount of the first read level based on the first number of mismatches.

19. The memory device according to claim 18, wherein the control circuit is further configured to:
acquire a third determination result of threshold voltages of the memory cells based on a first higher-voltage side offset read level, the first higher-voltage side offset read level is obtained by offsetting the first read level to a higher-voltage side;
acquire a second number of mismatches between the first determination result and the third determination result; and
calculate the first correction amount according to a magnitude relationship between the first number of mismatches and the second number of mismatches.

20. The memory device according to claim 19,
wherein, in a case where the first number of mismatches is larger than the second number of mismatches, the control circuit is configured to set the first correction amount to a value for shifting the first read level to the higher-voltage side, and
wherein, in a case where the first number of mismatches is smaller than the second number of mismatches, the control circuit is configured to set the first correction amount to a value for shifting the first read level to the lower-voltage side.

21. The memory device according to claim 18, wherein the control circuit is further configured to calculate the first correction amount in parallel with an output of the data based on the first determination result.

22. The memory device according to claim 18, wherein the control circuit is further configured to:
execute a first exclusive OR operation on the first determination result and the second determination result; and
acquire the first number of mismatches based on a number of “1”s in a result of the first exclusive OR operation.

23. The memory device according to claim 18, further comprising:
a first data latch that stores the first determination result;
a second data latch that stores the second determination result; and
a third data latch that stores a result of a first exclusive OR operation on the first determination result and the second determination result.
